(19) United States
(12) Patent Application Publication
(10) Pub. No.: US 2026/0239862 A1
(43) Pub. Date: Aug. 13, 2026

(54) DISPLAY PANEL, DISPLAY APPARATUS AND DRIVING METHOD THEREFOR

(71) Applicant: BOE TECHNOLOGY GROUP CO., LTD., Beijing (CN)

(72) Inventor: Mingche HSIEH, Beijing (CN)

(21) Appl. No.: 19/158,935

(22) PCT Filed: Feb. 18, 2024
(86) PCT No.: PCT/CN2024/077412

§ 371 Date: Aug. 22, 2025

(30) Foreign Application Priority Data
Mar. 10, 2023 (CN) 202310251624.X

(51) Int. Cl. H10K 59/80; G09G 3/3233; H10K 59/35; H10K 59/38

(52) U.S. Cl. CPC H10K 59/8792; G09G 3/3233; H10K 59/353; H10K 59/38; G09G 2300/0819; G09G 2320/068

(57) ABSTRACT

Disclosed are a display panel, a display apparatus and a driving method. The display panel includes a base substrate, a driving layer, a pixel layer and a viewing-angle definition layer stacked sequentially. The pixel layer includes sub-pixel groups arranged in an array, and any one of the sub-pixel groups includes a first sub-pixel and a second sub-pixel which are adjacent and have a same color. The viewing-angle definition layer is capable of making a light exit projection space of the first sub-pixel at most partially overlap with a light exit projection space of the second sub-pixel.

### CROSS-REFERENCE

The present disclosure is a U.S. National Stage of International Application No. PCT/CN 2024/077412, filed on Feb. 18, 2024, which claims priority to Chinese patent application number 202310251624.X filed on Mar. 10, 2023 and entitled “DISPLAY PANEL, DISPLAY DEVICE AND DRIVING METHOD THEREFOR”, the entire contents of both of which are incorporated herein by reference in their entirety.

### TECHNICAL FIELD

The present disclosure relates to the display technical field, and in particular, to a display panel, a display device and a driving method for driving the display device.

### BACKGROUND

As display products are increasingly used in a wide range of applications, there is a growing expectation for a single display product to meet requirements of diverse application scenarios as much as possible. For example, people expect that when they want to share information with others, the content displayed on a display product can be seen by others; also, people expect that when privacy information is displayed, it is difficult for others to see the displayed content.

Based on this demand, in some display products, an adjustable liquid crystal layer is set on a display screen, which limits a light exit angle through orientation of liquid crystal, thereby realizing switching between a privacy mode and a non-privacy mode. However, the thickness of the adjustable liquid crystal layer is relatively large, which is not conducive to the lightness and thinness of the display product.

It should be noted that the information disclosed in the background section is only used to enhance the understanding of the background of the present disclosure, and therefore may include information that does not constitute prior art known to those of ordinary skill in this art.

### SUMMARY

An objective of the present disclosure is to overcome the above-mentioned deficiency of the related art and provide a display panel, a display device and a driving method for driving the display device, which are conducive to lightness and thinness of the display panel.

According to a first aspect of the present disclosure, there is provided a display panel. The display panel includes a base substrate, a driving layer, a pixel layer and a viewing-angle definition layer stacked sequentially. The pixel layer includes sub-pixel groups arranged in an array, and any one of the sub-pixel groups includes a first sub-pixel and a second sub-pixel which are adjacent and have a same color;

where the viewing-angle definition layer is capable of making a light exit projection space of the first sub-pixel at most partially overlap with a light exit projection space of the second sub-pixel.

According to an implementation of the present disclosure, the viewing-angle definition layer includes a light-transmitting medium layer and a first color filter layer which are sequentially stacked at a side of the pixel layer away from the base substrate, the first color filter layer includes viewing-angle definition structures corresponding to the sub-pixel groups one to one, and the sub-pixel groups and corresponding viewing-angle definition structures constitute light exit units;

the light exit units includes a first light exit unit, and in the first light exit unit, the first sub-pixel is located at a first-direction side of the second sub-pixel, the viewing-angle definition structure includes a first light-shielding portion corresponding to the first sub-pixel, a second light-shielding portion corresponding to the second sub-pixel and a color resist unit between the first light-shielding portion and the second light-shielding portion, and a color of the color resist unit is the same as a light-emitting color of the sub-pixel group; an orthographic projection of the first light-shielding portion on the base substrate is at least partially located at a first-direction side of an orthographic projection of the first sub-pixel on the base substrate, and the first light-shielding portion exposes at least part of the first sub-pixel; an orthographic projection of the second light-shielding portion on the base substrate is at least partially located at a second direction side of an orthographic projection of the second sub-pixel on the base substrate, and the second light-shielding portion exposes at least part of the second sub-pixel, and the first direction is opposite to the second direction.

According to an implementation of the present disclosure, for two first light exit units which are adjacent along the first direction, a second light-shielding portion of a first light exit unit located at a side in the first direction is reused as a first light-shielding portion of a first light exit unit located at the second direction side.

According to an implementation of the present disclosure, the viewing-angle definition layer includes a light-transmitting medium layer and a first color filter layer which are sequentially stacked at a side of the pixel layer away from the base substrate, the first color filter layer includes viewing-angle definition structures corresponding to the sub-pixel groups one to one, and the sub-pixel groups and corresponding viewing-angle definition structures constitute light exit units;

the light exit units include a second light exit unit, and in the second light exit unit, the first sub-pixel is located at a third-direction side of the second sub-pixel, the viewing-angle definition structure includes a first light-shielding portion and a first color resist unit corresponding to the first sub-pixel, and a second light-shielding portion and a second color resist unit corresponding to the second sub-pixel, and colors of the first color resist unit and the second color resist unit are the same as a light-emitting color of the sub-pixel group; an orthographic projection of the first light-shielding portion on the base substrate is at least partially located at a first-direction side of an orthographic projection of the first sub-pixel on the base substrate, and the first light-shielding portion exposes at least part of the first sub-pixel; an orthographic projection of the first color resist unit on the base substrate is at least partially located at a second direction side of the orthographic projection of the first sub-pixel on the base substrate, and the first color resist unit extends along the first direction to be connected with the first light-shielding portion; an orthographic projection of the second light-shielding portion on the base substrate is at least partially located at a second direction side of an orthographic projection of the second sub-pixel on the base substrate, and the second light-shielding portion exposes at least part of the second sub-pixel; an orthographic projection of the second color resist unit on the base substrate is at least partially located at a first-direction side of the orthographic projection of the second sub-pixel on the base substrate, and the second color resist unit extends along the second direction to be connected with the second light-shielding portion, and the first direction is opposite to the second direction and is perpendicular to the third direction.

According to an implementation of the present disclosure, in at least part of the light exit units, the first sub-pixel partially overlaps with the first light-shielding portion, and a size of a part of the first sub-pixel overlapping with the first light-shielding portion in the first direction does not exceed half of a size of the first sub-pixel in the first direction;

and/or, in at least part of the light exit units, a second sub-pixel partially overlaps with a second light-shielding portion, a size of a part of the second sub-pixel overlapping with the second light-shielding portion in the first direction does not exceed half of a size of the second sub-pixel in the first direction.

According to an implementation of the present disclosure, a distance between the first color filter layer and the pixel layer is not smaller than a size of the sub-pixel group along the first direction.

According to an implementation of the present disclosure, the viewing-angle definition layer further includes a first black matrix layer between the pixel layer and the light-transmitting medium layer;

the viewing-angle definition structure further includes a first bottom light-shielding portion and a second bottom light-shielding portion located in the first black matrix layer, an orthographic projection of the first bottom light-shielding portion on the base substrate does not exceed the orthographic projection of the first light-shielding portion on the base substrate, and an orthographic projection of the second bottom light-shielding portion on the base substrate does not exceed the orthographic projection of the second light-shielding portion on the base substrate.

According to an implementation of the present disclosure, the viewing-angle definition layer includes a first black matrix layer, a light-transmitting medium layer and a second black matrix layer which are sequentially stacked at a side of the pixel layer away from the base substrate, the viewing-angle definition layer has viewing-angle definition structures corresponding to the sub-pixel groups one to one, and the sub-pixel groups and corresponding viewing-angle definition structures form light exit units;

the light exit units include a first light exit unit, and in the first light exit unit, the first sub-pixel is located at a first-direction side of the second sub-pixel, the viewing-angle definition structure includes a first light-shielding portion and a first bottom light-shielding portion corresponding to the first sub-pixel, and a second light-shielding portion and a second bottom light-shielding portion corresponding to the second sub-pixel; the first bottom light-shielding portion and the second bottom light-shielding portion are located in the first black matrix layer, and the first light-shielding portion and the second light-shielding portion are located in the second black matrix layer; an orthographic projection of the first light-shielding portion on the base substrate is at least partially located at a first-direction side of an orthographic projection of the first sub-pixel on the base substrate, and the first light-shielding portion exposes at least part of the first sub-pixel; an orthographic projection of the first bottom light-shielding portion on the base substrate is at least partially located at a first-direction side of the orthographic projection of the first sub-pixel on the base substrate, and the first bottom light-shielding portion exposes at least part of the first sub-pixel; an orthographic projection of the second light-shielding portion on the base substrate is at least partially located at a second direction side of an orthographic projection of the second sub-pixel on the base substrate, and the second light-shielding portion exposes at least part of the second sub-pixel; an orthographic projection of the second bottom light-shielding portion on the base substrate is at least partially located at a second direction side of the orthographic projection of the second sub-pixel on the base substrate, and the second bottom light-shielding portion exposes at least part of the second sub-pixel, and the first direction is opposite to the second direction.

According to an implementation of the present disclosure, for two first light exit units which are adjacent along the first direction, a second light-shielding portion of a first light exit unit located at the first-direction side is reused as a first light-shielding portion of a first light exit unit located at the second-direction side, and a second bottom light-shielding portion of the first light exit unit located at the first-direction side is reused as a first bottom light-shielding portion of the first light exit unit located at the second-direction side.

According to an implementation of the present disclosure, the viewing-angle definition layer includes a first black matrix layer, a light-transmitting medium layer, and a second black matrix layer which are sequentially stacked at a side of the pixel layer away from the base substrate, the viewing-angle definition layer has viewing-angle definition structures corresponding to the sub-pixel groups one to one, and the sub-pixel groups and corresponding viewing-angle definition structures form light exit units;

the light exit units include a second light exit unit, and in the second light exit unit, the first sub-pixel is located at a third-direction side of the second sub-pixel, the viewing-angle definition structure includes a first light-shielding portion and a first bottom light-shielding portion corresponding to the first sub-pixel, and a second light-shielding portion and a second bottom light-shielding portion corresponding to the second sub-pixel; the first bottom light-shielding portion and the second bottom light-shielding portion are located in the first black matrix layer, and the first light-shielding portion and the second light-shielding portion are located in the second black matrix layer; an orthographic projection of the first light-shielding portion on the base substrate is at least partially located at a first-direction side of an orthographic projection of the first sub-pixel on the base substrate, and the first light-shielding portion exposes at least part of the first sub-pixel; an orthographic projection of the first bottom light-shielding portion on the base substrate is at least partially located at a first-direction side of the orthographic projection of the first sub-pixel on the base substrate, and the first bottom light-shielding portion exposes at least a part of the first sub-pixel; an orthographic projection of the second light-shielding portion on the base substrate is at least partially located at a second direction side of an orthographic projection of the second sub-pixel on the base substrate, and the second light-shielding portion exposes at least part of the second sub-pixel; an orthographic projection of the second bottom light-shielding portion on the base substrate is at least partially located at a second direction side of the orthographic projection of the second sub-pixel on the base substrate, and the second bottom light-shielding portion exposes at least part of the second sub-pixel, and the first direction is opposite to the second direction and is perpendicular to the third direction.

According to an implementation of the present disclosure, a distance between the second black matrix layer and the pixel layer is not smaller than a size of the sub-pixel group along the first direction.

According to an implementation of the present disclosure, in at least part of the light exit units, the first sub-pixel partially overlaps with the first bottom light-shielding portion, a size of a part of the first sub-pixel overlapping with the first bottom light-shielding portion in the first direction does not exceed half of a size of the first sub-pixel in the first direction; the first sub-pixel partially overlaps with the first light-shielding portion, and a size of a part of the first sub-pixel overlapping with the first light-shielding portion in the first direction does not exceed half of the size of the first sub-pixel in the first direction;

and/or, in at least part of the light exit unit, the second sub-pixel partially overlaps with the second bottom light-shielding portion, and a size of a part of the second sub-pixel overlapping with the second bottom light-shielding portion in the first direction does not exceed half of a size of the second sub-pixel in the first direction; the second sub-pixel partially overlaps with the second light-shielding portion, and a size of a part of the second sub-pixel overlapping with the second light-shielding portion in the first direction does not exceed half of the size of the second sub-pixel in the first direction.

According to an implementation of the present disclosure, the viewing-angle definition layer includes a first black matrix layer, a light-transmitting medium layer and a second color filter layer which are sequentially stacked at a side of the pixel layer away from the base substrate, the viewing-angle definition layer includes viewing-angle definition structures corresponding to the sub-pixel groups one to one, and the sub-pixel groups and corresponding viewing-angle definition structures constitute light exit units;
the light exit units includes a first light exit unit, and in the first light exit unit, the first sub-pixel is located at a first-direction side of the second sub-pixel, the viewing-angle definition structure includes a first color resist unit corresponding to the first sub-pixel, a second color resist unit corresponding to the second sub-pixel, an auxiliary color resist unit between the first color resist unit and the second color resist unit, and a bottom light-shielding portion located in the first black matrix layer;
the first color resist unit, the second color resist unit and the auxiliary color resist unit are located in the second color filter layer, colors of the first color resist unit and the second color resist unit are the same as a light-emitting color of the sub-pixel group, and a color of the auxiliary color resist unit is different from the light-emitting color of the sub-pixel group;
an orthographic projection of the first color resist unit on the base substrate is located at a first-direction side of an orthographic projection of the first sub-pixel on the base substrate, and an orthographic projection of the second color resist unit on the base substrate is located at a second direction side of an orthographic projection of the second sub-pixel on the base substrate, an orthographic projection of the bottom light-shielding portion on the base substrate at least covers an orthographic projection of a gap between the first sub-pixel and the second sub-pixel on the base substrate; a light path between the second sub-pixel and the first color resist unit is blocked by the bottom light-shielding portion, and a light path between the first sub-pixel and the second color resist unit is blocked by the bottom light-shielding portion; the first direction is opposite to the second direction.

According to an implementation of the present disclosure, in at least part of the first light exit units, the bottom light-shielding portion partially overlaps with the first sub-pixel, and a size of a part of the first sub-pixel overlapping with the bottom light-shielding portion in the first direction does not exceed half of a size of the first sub-pixel in the first direction;

and/or, in at least part of the first light exit unit, the second sub-pixel partially overlaps with the bottom light-shielding portion, and a size of a part of the second sub-pixel overlapping with the bottom light-shielding portion in the first direction does not exceed half of a size of the second sub-pixel in the first direction.

According to an implementation of the present disclosure, the auxiliary color resist unit includes a first auxiliary color resist unit and a second auxiliary color resist unit, and the first auxiliary color resist unit is located at a first-direction side of the second auxiliary color resist unit;
for two first light exit units which are adjacent along the first direction, a second auxiliary color resist unit of a first light exit unit located at the first-direction side is reused as a first color resist unit of a first light exit unit located at the second-direction side, and a first auxiliary color resist unit of the first light exit unit located at the second-direction side is reused as a second color resist unit of the first light exit unit located at the first-direction side.

According to an implementation of the present disclosure, in at least part of the first light exit units, the auxiliary color resist unit includes a first auxiliary color resist unit and a second auxiliary color resist unit, and the first auxiliary color resist unit is located at a first-direction side of the second auxiliary color resist unit; an orthographic projection of the first auxiliary color resist unit on the base substrate covers the orthographic projection of the first sub-pixel on the base substrate, and an orthographic projection of the second auxiliary color resist unit on the base substrate covers the orthographic projection of the second sub-pixel on the base substrate.

According to an implementation of the present disclosure, in at least part of the first light exit units, the auxiliary color resist unit includes a first auxiliary color resist unit and a second auxiliary color resist unit, and the first auxiliary color resist unit is located at a first-direction side of the second auxiliary color resist unit, and the first light exit unit further includes a light-shielding portion between the first auxiliary color resist unit and the second auxiliary color resist unit and arranged in the second color filter layer.

According to an implementation of the present disclosure, the viewing-angle definition layer includes a first black matrix layer, a light-transmitting medium layer, and a second color filter layer which are sequentially stacked at a side of the pixel layer away from the base substrate, the viewing-angle definition layer includes viewing-angle definition structures corresponding to the sub-pixel groups one to one, and the sub-pixel groups and corresponding viewing-angle definition structures constitute light exit units;
the light exit units includes a second light exit unit, and in the second light exit unit, the first sub-pixel is located at a third-direction side of the second sub-pixel, the viewing-angle definition structure includes a first color resist unit and a first bottom light-shielding portion corresponding to the first sub-pixel, a second color resist unit and a second bottom light-shielding portion corresponding to the second sub-pixel, and an auxiliary color resist unit between the first color resist unit and the second color resist unit; the first color resist unit, the second color resist unit and the auxiliary color resist unit are located in the second color filter layer, and colors of the first color resist unit and the second color resist unit are the same as a light-emitting color of the sub-pixel group, and a color of the auxiliary color resist unit is different from the light-emitting color of the sub-pixel group; the first bottom light-shielding portion and the second bottom light-shielding portion are located in the first black matrix layer; an orthographic projection of the first color resist unit on the base substrate is located at a first-direction side of an orthographic projection of the first sub-pixel on the base substrate; an orthographic projection of the second color resist unit on the base substrate is located at a second direction side of an orthographic projection of the second sub-pixel on the base substrate; an orthographic projection of the first bottom light-shielding portion on the base substrate is at least partially located at a second direction side of the orthographic projection of the first sub-pixel on the base substrate; an orthographic projection of the second bottom light-shielding portion on the base substrate is at least partially located at a first-direction side of the orthographic projection of the second sub-pixel on the base substrate; a light path between the second sub-pixel and the first color resist unit is blocked by the second bottom light-shielding portion, and a light path between the first sub-pixel and the second color resist unit is blocked by the first bottom light-shielding portion; the first direction is opposite to the second direction and is perpendicular to the third direction.

According to an implementation of the present disclosure, a distance between the second color filter layer and the pixel layer is not smaller than a size of the sub-pixel group along the first direction.

According to an implementation of the present disclosure, the driving layer has pixel driving circuit groups corresponding to the sub-pixel groups one to one, and the pixel driving circuit group includes a first pixel driving circuit for driving the first sub-pixel and a second pixel driving circuit for driving the second sub-pixel;

the first pixel driving circuit and the second pixel driving circuit share a part of transistors.

According to an implementation of the present disclosure, the pixel driving circuit group includes:
a pixel driving module configured to provide a driving current;
a first light-emitting control module configured to, in response to a first light-emitting control signal, cause the driving current to flow to the first sub-pixel; and a second light-emitting control module configured to, in response to a second light-emitting control signal, cause the driving current flow to the second sub-pixel.

According to an implementation of the present disclosure, the pixel driving circuit group further includes:
a first reset module configured to reset a voltage on a pixel electrode of the first sub-pixel in response to a first electrode reset signal; and
a second reset module configured to reset a voltage on a pixel electrode of the second sub-pixel in response to a second electrode reset signal.

According to an implementation of the present disclosure, one of the first light-emitting control module and the second light-emitting control module is an N-type transistor, and the other one of the first light-emitting control module and the second light-emitting control module is a P-type transistor, and a gate of the N-type transistor and a gate of the P-type transistor are connected to a same light-emitting control signal line.

According to an implementation of the present disclosure, the pixel layer includes a pixel electrode layer, a pixel definition layer, a light-emitting function layer and a common electrode layer which are sequentially stacked;
the pixel electrode layer is provided with a pixel electrode of the first sub-pixel and a pixel electrode of the second sub-pixel;
the pixel definition layer has a first sub-pixel opening exposing at least part of a region of the pixel electrode of the first sub-pixel and a second sub-pixel opening exposing at least part of a region of the pixel electrode of the second sub-pixel;
the light-emitting function layer has light-emitting functional unit groups corresponding to the sub-pixel groups, and the light-emitting functional unit group covers the first sub-pixel opening and the second sub-pixel opening and covers a region between the first sub-pixel opening and the second sub-pixel opening.

According to a second aspect of the present disclosure, there is provided a display device including the display panel described above.

According to a third aspect of the present disclosure, there is provided a driving method for driving a display device. The method includes:
at a first moment, enabling each of first sub-pixels to emit light to display a first image; and
at a second moment, enabling each of second sub-pixels to emit light to display a second image.

According to an implementation of the present disclosure, the driving method further includes:
in response to a switching instruction, performing switching between a privacy mode and a non-privacy mode,
the first image and the second image are different in the privacy mode;
the first image and the second image are the same in the non-privacy mode.

It is to be understood that the foregoing general description and the following detailed description are illustrative and explanatory only and are not restrictive of the present disclosure.

### BRIEF DESCRIPTION OF THE DRAWINGS

The accompanying drawings herein, which are incorporated into the specification and constitute a part of the specification, illustrate embodiments consistent with the present disclosure, and together with the specification are used to explain the principles of the present disclosure. Obviously, the accompanying drawings described below are only a part of embodiments of the present disclosure, and for those of ordinary skill in this art, other accompanying drawings can be obtained based on these accompanying drawings without creative work.

FIG. 1 is a schematic diagram showing the principle of a display panel in an implementation of the present disclosure.

FIG. 2 is a schematic diagram showing the principle of a display panel in an implementation of the present disclosure.

FIG. 3 is a schematic flowchart of a driving method for driving a display device in an implementation of the present disclosure.

FIG. 4 is a schematic diagram of a structure of a display panel in an implementation of the present disclosure.

FIG. 5-1 is a schematic diagram of an arrangement of sub-pixels in related art.

FIG. 5-2 is a schematic diagram of an arrangement of sub-pixels in an implementation of the present disclosure.

FIG. 6-1 is a schematic diagram of an arrangement of sub-pixels in related art.

FIG. 6-2 is a schematic diagram of an arrangement of sub-pixels in an implementation of the present disclosure.

FIG. 7-1 is a schematic diagram of an arrangement of sub-pixels in related art.

FIG. 7-2 is a schematic diagram of an arrangement of sub-pixels in an implementation of the present disclosure.

FIG. 8 is a schematic diagram of a partial structure of a display panel in an implementation of the present disclosure.

FIG. 9 is a schematic diagram showing the principle of a pixel driving circuit group in an implementation of the present disclosure.

FIG. 10 is a schematic diagram showing the principle of a pixel driving circuit group in an implementation of the present disclosure.

FIG. 11 is a schematic diagram of a structure of a pixel driving circuit group in an implementation of the present disclosure.

FIG. 12-1 is a schematic diagram of a structure of a pixel driving circuit group in an implementation of the present disclosure.

FIG. 12-2 is a schematic diagram of a structure of a pixel driving circuit group in an implementation of the present disclosure.

FIG. 13 is a schematic diagram of the principle of a first light exit unit in an implementation of the present disclosure.

FIG. 14 is a schematic diagram of the principle of a first light exit unit in an implementation of the present disclosure.

FIG. 15 is a schematic diagram of the structure of the cooperation between a pixel layer and a viewing-angle definition layer in an implementation of the present disclosure.

FIG. 16 is a schematic diagram of the principle of a first light exit unit in an implementation of the present disclosure.

FIG. 17 is a schematic diagram of a structure of a second light exit unit in an implementation of the present disclosure.

FIG. 18 is a schematic diagram of the principle of a first light exit unit in an implementation of the present disclosure.

FIG. 19 is a schematic diagram of the principle of a first light exit unit in an implementation of the present disclosure.

FIG. 20 is a schematic diagram of the structure of the cooperation between a pixel layer and a viewing-angle definition layer in an implementation of the present disclosure.

FIG. 21 is a schematic diagram of a structure of a second light exit unit in an implementation of the present disclosure.

FIG. 22 is a schematic diagram of the principle of a first light exit unit in an implementation of the present disclosure.

FIG. 23 is a schematic diagram of the principle of a first light exit unit in an implementation of the present disclosure.

FIG. 24 is a schematic diagram of the structure of the cooperation between a pixel layer and a viewing-angle definition layer in an embodiment of the present disclosure.

FIG. 25 is a schematic diagram of a structure of a second light exit unit in an implementation of the present disclosure.

FIG. 26 is a schematic diagram of a structure in which a display backplane is formed in an implementation of the present disclosure.

FIG. 27 is a schematic diagram of a structure in which a touch function layer is formed on the display backplane in an implementation of the present disclosure.

FIG. 28 is a schematic diagram of a structure in which a light-transmitting medium layer is formed on the touch function layer in an implementation of the present disclosure.

FIG. 29 is a schematic diagram of a structure in which a first color filter layer is formed on a light-transmitting medium layer in an implementation of the present disclosure.

### DETAILED DESCRIPTION

Example implementations will now be described more fully with reference to the accompanying drawings. However, the example implementations can be implemented in a variety of forms and should not be construed as limited to the implementations set forth herein; rather, these implementations are provided so that the present disclosure will be comprehensive and complete and fully convey the concepts of the example implementations to those skilled in the art. The same reference numerals in the figures represent the same or similar structures, and thus their detailed description will be omitted. In addition, the drawings are only schematic illustrations of the present disclosure and are not necessarily drawn to scale.

Although relative terms such as “upper” and “lower” are used in the specification to describe a relative relationship of one component shown in a figure with respect to another component, these terms are used in the specification only for convenience, for example, the terms are based on orientations of examples described in the drawings. It is understood that if a device shown in a figure is turned upside down, a component described as “upper” will become a component “lower”. When a structure is “on” another structure, it may mean that the structure is formed integrally on another structure, or that the structure is “directly” disposed on another structure, or that the structure is “indirectly” disposed on another structure through other structure(s).

The terms “a”, “an”, “the”, “said” and “at least one” are used to indicate the presence of one or more elements/components/etc. ; the terms “including/comprising” and “having” are used to express an open-ended inclusive meaning and mean that additional elements/components/etc. may exist in addition to the listed elements/components/etc. ; the terms “first”, “second” and “third” etc. are used merely as markers and are not intended to limit the quantity of associated objects.

In an implementation of the present disclosure, a transistor refers to an element including at least three terminals: a gate, a drain, and a source. The transistor has a channel region between the drain (a drain electrode terminal, a drain region, or a drain electrode) and the source (a source electrode terminal, a source region, or a source electrode), and current may flow through the drain, the channel region, and the source. The channel region refers to a region which the current mainly flows through. A first terminal of a transistor may be a drain, and a second terminal may be a source; alternatively, the first terminal of the transistor may be a source, and the second terminal may be a drain. In a case of using transistors of opposite polarity or in a case of a change in the direction of current during circuit operation, the functions of the “source” and the “drain” are sometimes interchanged.

In an implementation of the present disclosure, when describing that a structure A overlaps with a structure B, it means that an orthographic projection of the structure A on a base substrate and an orthographic projection of the structure B on the base substrate at least have an overlapping region. When describing that a structure A partially overlaps with a structure B, it means that the orthographic projection of structure A on the base substrate and the orthographic projection of structure B on the base substrate only partially overlap with each other.

In an implementation of the present disclosure, when describing that a structure C exposes a structure D or describing that the structure D is exposed by the structure C, it means that the structure C is located at a side of the structure D away from the base substrate, but an orthographic projection of the structure C on the base substrate does not overlap with an orthographic projection of structure D on the base substrate.

In an implementation of the present disclosure, a structure layer being located at a side of a structure layer F away from the base substrate may be understood as: the structure layer E is formed at a side of the structure layer F away from the base substrate. When the structure layer F is a patterned structure, a part of the structure layer E may also be located at the same physical height of the structure layer F or lower than the physical height of the structure layer F, where the base substrate is a height reference.

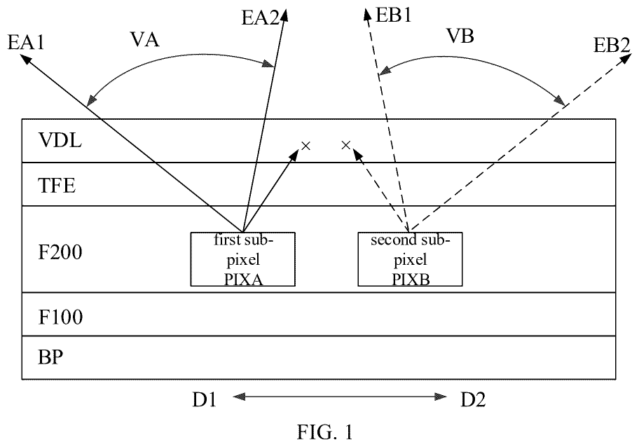

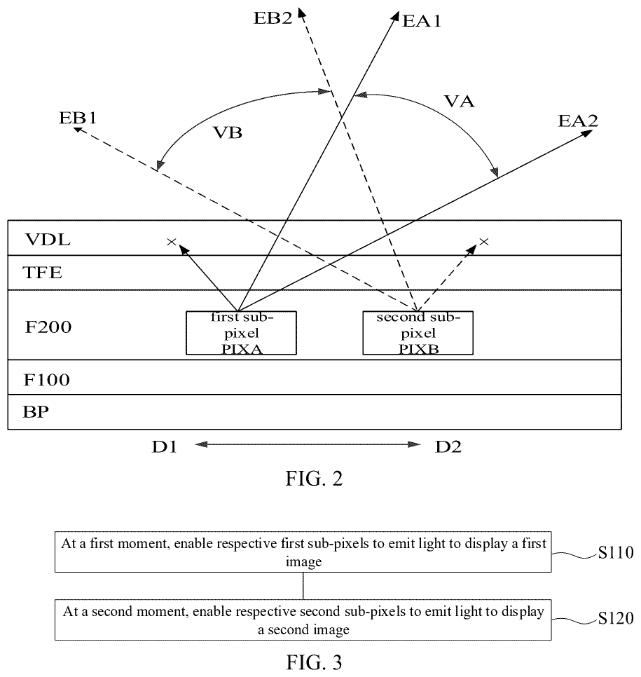

An implementation of the present disclosure provides a display panel and a display device in which the display panel is applied. Referring to FIG. 1 and FIG. 2, the display panel includes a base substrate BP, a driving layer F100, a pixel layer F200 and a viewing-angle definition layer VDL which are sequentially stacked. The pixel layer F200 includes sub-pixel groups PIXS arranged in an array, and any one of the sub-pixel groups PIXS includes a first sub-pixel PIXA and a second sub-pixel PIXB which are adjacent and of the same color. The viewing-angle definition layer VDL can make a light exit projection space VA of the first sub-pixel PIXA at most partially overlap with a light exit projection space VB of the second sub-pixel PIXB. A light exit projection space of a sub-pixel is a space corresponding to a light exit angle range of the sub-pixel.

For example, first sub-pixels PIXA of respective sub-pixel groups PIXS are used as a first sub-pixel cluster for displaying a first image, and second sub-pixels PIXB of respective sub-pixel group PIXS are used as a second sub-pixel cluster for displaying a second image. The viewing-angle definition layer VDL is configured to make a viewing angle range of the first sub-pixel cluster at most partially overlap with a viewing angle range of the second sub-pixel cluster, such as partially overlap or completely separate.

When the display device is driven, referring to FIG. 3, the following driving method may be used:

In step S110, each of the first sub-pixels PIXA is enabled to emit light to display a first image.

In step S120, each of the second sub-pixels PIXB is enabled to emit light to display a second image.

In other words, in the implementation, each first sub-pixel PIXA is used to display a first image. When a user is in a light exit projection space VA of the first sub-pixel PIXA, the first image can be seen from the display panel. Each second sub-pixel PIXB is used to display a second image. When a user is in a light exit projection space VB of the second sub-pixel PIXB, the second image can be seen from the display panel. If the first image and the second image are the same, different users in the light exit projection space VA of the first sub-pixel PIXA and the light exit projection space VB of the second sub-pixel PIXB can see the images on the display panel, and the images are the same. At this time, the display device is in a non-privacy mode. If the first image and the second image are not the same, different users in the light exit projection space VA of the first sub-pixel PIXA and the light exit projection space VB of the second sub-pixel PIXB can see different images on the display panel, respectively, and the display device is in a privacy mode. In the privacy mode, one of the first image and the second image may be a target image, and the other may be a non-target image, for example, a black image, a screen saver image or other non-target image. Of course, in other implementations of the present disclosure, the first image and the second image may both be target images, so that the display panel can simultaneously meet the usage requirements of two different users. For example, the first image is a target image for a first user located in the light exit projection space VA of the first sub-pixel PIXA, and the second image is a target image for a second user located in the light exit projection space VB of the second sub-pixel PIXB.

In the implementation, the viewing-angle definition layer VDL does not need to be provided with an adjustable device, such as a liquid crystal layer. This avoids the excessive thickness of the film layer caused by the provision of a structure such as a liquid crystal layer. This can achieve the switching between the privacy mode and the non-privacy mode without significantly increasing the thickness of the display panel.

In some implementations of the present disclosure, the driving method for driving the display device of the present disclosure further includes: in response to a switching instruction, performing switching between the privacy mode and the non-privacy mode. For example, a mode switching button may be provided on the display device, and the button may be a physical button or a virtual button. The switching between the privacy mode and the non-privacy mode is realized through the switching button.

In an example, the privacy mode may also include a first privacy mode and a second privacy mode. In the first privacy mode, the first image is a target image, and the second image is a non-target image. In the second privacy mode, the first image is a non-target image, and the second screen is a target image. When a user is located in the light exit projection space VA of the first sub-pixel PIXA, the first privacy mode may be adopted. When the user is located in the light exit projection space VB of the second sub-pixel PIXB, the second privacy mode may be adopted.

In an example, the non-target image may be a black image (i.e., a black screen) or other preset images, such as a screen saver image, a random and chaotic image, a dynamic image, and the like.

In an implementation of the present disclosure, the first sub-pixel PIXA and the second sub-pixel PIXB in a sub-pixel group PIXS may emit light in a time division manner instead of emitting light at the same time. For example, the first sub-pixel PIXA and the second sub-pixel PIXB may emit light alternately. For example, in step S110, at a first moment, each of the first sub-pixels PIXA emits light to display a first image. In step S120, at a second moment, each of the second sub-pixels PIXB emits light to display a second image. There is no overlap between the first moment and the second moment. In this way, the complexity of the driving method and the complexity of the driving circuit can be reduced, thereby reducing the development cost and power consumption of the display panel, and helping to maintain or even improve the resolution of the display panel.

In an example, the display panel alternately displays the first image and the second image. In this way, the displaying of the first image and the second image can be achieved by reducing the refresh rate of the first image and the second image. For example, if the total refresh rate of the display panel is 120 Hz, the refresh rate of the first image is 60 Hz, and the refresh rate of the second image is 60 Hz. In this way, the signal source does not need to perform pre-fusion of the first image and the second image, but directly makes the first sub-pixel PIXA display the first image and makes the second sub-pixel PIXB display the second image, so as to achieve image fusion at the physical level.

In an example, the light exit projection space VA of the first sub-pixel PIXA is at least partially located at a first direction D1 side of the display panel, and the light exit projection space VB of the second sub-pixel PIXB is at least partially located at a second direction D2 side of the display panel. The first direction D1 and the second direction D2 are two opposite directions, for example, the left and right sides of the display device, and in particular, the left and right sides of a mobile terminal such as a smart phone or a tablet computer, etc.

As follows, the structure, principle and effect of the display panel in the implementations of the present disclosure are further explained and illustrated in conjunction with the accompanying drawings.

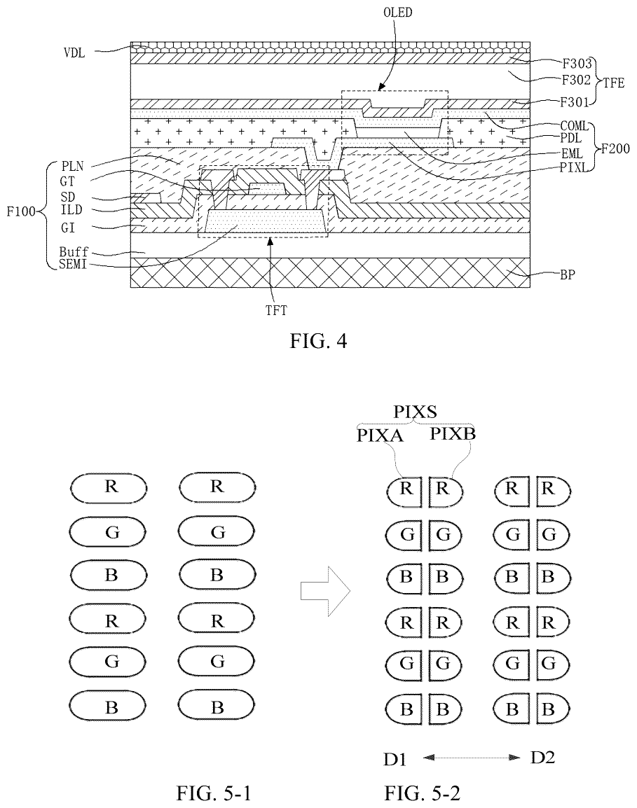

Referring to FIG. 4, in an implementation of the present disclosure, the display panel includes a base substrate BP, a driving layer F100, a pixel layer F200, an encapsulation layer TFE and a viewing-angle definition layer VDL which are sequentially stacked. The pixel layer F200 is provided with sub-pixels for display, and the driving layer F100 is provided with pixel driving circuits for driving the sub-pixels.

In some implementations of the present disclosure, the base substrate BP may be a base substrate BP of an inorganic material, or a base substrate BP of an organic material. For example, in an implementation of the present disclosure, the material of the base substrate BP may be a glass material such as soda-lime glass, quartz glass, sapphire glass, etc. In another implementation of the present disclosure, the material of the base substrate BP may be polymethyl methacrylate, polyvinyl alcohol, polyvinyl phenol, polyether sulfone, polyimide, polyamide, polyacetal, polycarbonate, polyethylene terephthalate, polyethylene naphthalate, or a combination thereof. In another implementation of the present disclosure, the base substrate BP may also be a flexible base substrate BP, for example, the material of the base substrate BP may be polyimide.

The driving layer F100 is provided with pixel driving circuits for driving sub-pixels. In the driving layer F100, any one of the pixel driving circuits may include a transistor TFT and a storage capacitor. Further, the transistor TFT may be a thin film transistor, and the thin film transistor may be selected from a top-gate thin film transistor, a bottom-gate thin film transistor or a double-gate thin film transistor. The material of a active layer of the thin film transistor may be an amorphous silicon semiconductor material, a low-temperature polycrystalline silicon semiconductor material, a metal oxide semiconductor material, an organic semiconductor material or other types of semiconductor materials. The thin film transistor may be an N-type thin film transistor or a P-type thin film transistor.

It is understandable that, among transistors in a pixel driving circuit, the types of any two transistors may be the same or different. As an example, in an implementation, in a pixel driving circuit, a part of transistors may be N-type transistors and a part of transistors may be P-type transistors. As another example, in another implementation of the present disclosure, in a pixel driving circuit, the material of the active layers of a part of transistors may be a low-temperature polysilicon semiconductor material, and the material of the active layers of a part of transistors may be a metal oxide semiconductor material. In some implementations of the present disclosure, the thin film transistors are low-temperature polysilicon transistors. In some other implementations of the present disclosure, a part of thin film transistors are low-temperature polysilicon transistors, and a part of thin film transistors are metal oxide transistors.

Optionally, the driving layer F100 may include a semiconductor layer SEMI, a gate insulating layer GI, a gate layer GT, an interlayer dielectric layer ILD, and a source-drain metal layer SD, etc., stacked between the base substrate BP and the pixel layer F200. Each thin film transistor and the storage capacitor may be formed by film layers such as the semiconductor layer SEMI, the gate insulating layer GI, the gate layer GT, the interlayer dielectric layer ILD, the source-drain metal layer SD, etc. The positional relationships of respective film layers may be determined according to the film layer structure of the thin film transistor. Further, the semiconductor layer SEMI may be used to form a channel region of a transistor. The gate layer may be used to form gate layer lines, such as a scan line, a reset control line, a light-emitting control line, etc., and may also be used to form the gate of a transistor, and may also be used to form a part or all of electrode plates of the storage capacitor. The source-drain metal layer may be used to form source-drain metal layer lines, such as a data voltage line, a driving voltage line, etc., and may also be used to form a part of the electrode plates of the storage capacitor.

In an example, referring to FIG. 4, the driving layer F100 may include an inorganic buffer layer Buff, a semiconductor layer SEMI, a gate insulating layer GI, a gate layer GT, an interlayer dielectric layer ILD, a source-drain metal layer SD and a planarization layer PLN which are stacked in sequence, and a thin film transistor formed in this way is a top-gate thin film transistor. Of course, it can be understood that the driving layer F100 of the present disclosure may also have other forms of stacked structures, such as having two or more than three semiconductor layers SEMI, or having two or more gate layers GT, or having two or more source-drain metal layers SD, etc. When the number of these semiconductor layers or conductive film layers increases, the insulating film layer may also be adaptively increased.

Optionally, the driving layer F100 may further include a passivation layer. The passivation layer may be disposed on a surface of the source-drain metal layer SD away from the base substrate BP so as to protect the source-drain metal layer SD.

The pixel layer F200 may be provided with light-emitting elements electrically connected to corresponding pixel driving circuits, and the light-emitting elements may be used as the sub-pixels of the display panel. In an example, the light-emitting elements used as the sub-pixels are Organic Light-Emitting Diodes (OLEDs). It is understood that in other implementations of the present disclosure, the sub-pixels may also be other types of light-emitting elements, in particular, may be electroluminescent elements, such as current-driven light-emitting elements such as QLED, PLED, Micro LED, Mini LED, etc.

In some implementations of the present disclosure, a light-emitting element in the pixel layer F200 is a thin-film light-emitting element, which may include two electrodes stacked and a light-emitting functional unit sandwiched between the two electrodes. For example, referring to FIG. 4, the pixel layer F200 may be arranged at a side of the driving layer F100 away from the base substrate BP, and may include a pixel electrode layer PIXL, a pixel definition layer PDL, a light-emitting functional layer EML and a common electrode layer COML stacked in sequence. The pixel electrode layer PIXL has a plurality of pixel electrodes in a display region of the display panel. The pixel definition layer PDL has a plurality of through pixel openings corresponding to the plurality of pixel electrodes in the display region one to one, and any one of the pixel openings exposes at least part of a region of a corresponding pixel electrode. The light-emitting functional layer EML at least covers the pixel electrodes exposed by the pixel definition layer PDL. The common electrode layer COML may cover the light-emitting functional layer EML in the display region. The pixel electrode and the common electrode layer COML provide carriers such as electrons and holes to the light-emitting functional layer EML, so that the light-emitting functional layer EML emits light. The part of the light-emitting functional layer EML located between the pixel electrode and the common electrode layer COML may be used as a light-emitting functional unit. The pixel electrode, the common electrode layer COML, and the light-emitting functional unit form a light-emitting element. Any one light-emitting element may be used as a sub-pixel of the display panel, for example, may be used as one of the first sub-pixel and the second sub-pixel.

It is understandable that if the type of light-emitting element is different, the material and film layer of the light-emitting functional layer EML are different; correspondingly, the light-emitting functional unit of the light-emitting element is different. For example, when the light-emitting element is an OLED, the light-emitting functional layer EML may include an organic electroluminescent material layer, and may include one or more of a hole injection layer, a hole transport layer, an electron blocking layer, a hole blocking layer, an electron transport layer and an electron injection layer. When the OLED adopts a tandem structure, a charge generation layer may also be provided in the light-emitting functional layer EML.

For another example, when the light-emitting element is a QLED, the light-emitting functional layer EML may include a quantum dot material layer, and may include one or more of a hole injection layer, a hole transport layer, an electron blocking layer, a hole blocking layer, an electron transport layer, and an electron injection layer. When the QLED adopts a tandem structure, a charge generation layer may also be provided in the light-emitting functional layer EML.

Optionally, referring to FIG. 4, the display panel may further include an encapsulation layer TFE. The encapsulation layer TFE may be a thin film encapsulation layer, which is disposed on a surface of the pixel layer F200 away from the base substrate BP, and may include an inorganic encapsulation layer and an organic encapsulation layer alternately stacked. The inorganic encapsulation layer can effectively block moisture and oxygen from the outside, and prevent moisture and oxygen from invading the pixel layer F200 and causing aging of the material in the pixel layer F200. Optionally, an edge of the inorganic encapsulation layer may be located in a peripheral region. The organic encapsulation layer is located between two adjacent inorganic encapsulation layers to achieve planarization and reduction of the stress between the inorganic encapsulation layers. An edge of the organic encapsulation layer may be located between an edge of the display region and an edge of the inorganic encapsulation layer. As an example, the encapsulation layer TFE includes a first inorganic encapsulation layer F301, an organic encapsulation layer F302, and a second inorganic encapsulation layer F303 sequentially stacked at a side of the pixel layer F200 away from the base substrate BP. Of course, in other implementations of the present disclosure, the display panel may not be provided with a thin film encapsulation layer, but the pixel layer may be encapsulated and protected in other ways.

In an implementation of the present disclosure, a product formed by the base substrate, the driving layer, the pixel layer and the encapsulation layer may be called a display backplane. In the implementation of the present disclosure, a viewing-angle definition layer may be set on the light-exit side of the display backplane to enable the display panel to have a privacy protection function.

Optionally, the display panel may further include a functional layer, such as a touch function layer. The functional layer may be located between the encapsulation layer TFE and the viewing-angle definition layer VDL, and is used to implement a preset function. For example, the display panel includes a touch function layer arranged between the encapsulation layer TFE and the viewing-angle definition layer VDL, and the touch function layer enables the display panel to have a touch function.

In an implementation of the present disclosure, the first sub-pixel PIXA and the second sub-pixel PIXB are arranged adjacently and of the same color. On the one hand, this is conducive to the design of the display panel. Each first sub-pixel PIXA and the second sub-pixel PIXB can be designed according to a sub-pixel group PIXS, without having to design the first sub-pixel PIXA and the second sub-pixel PIXB separately. On the other hand, this is also conducive to the driving of the display panel, enabling the first sub-pixel PIXA and the second sub-pixel PIXB to be applicable to the same driving timing, without having to set differentiated driving timings for the first sub-pixel PIXA and the second sub-pixel PIXB respectively. Therefore, the display panel has the advantages of simple design and easy driving development. Also, since the first sub-pixel PIXA and the second sub-pixel PIXB are of the same color, the spacing between the first sub-pixel PIXA and the second sub-pixel PIXB can be small, and there is no need to worry about the problem of the materials of the first sub-pixel PIXA and the second sub-pixel PIXB being mixed with each other during preparation. This makes the layout density of the sub-pixel groups PIXS larger, which is conducive to improving the resolution of the display panel. When the light exit projection space VA of the first sub-pixel PIXA and the light exit projection space VB of the second sub-pixel PIXB have an overlapping space, in the non-privacy mode, the first image and the second image seen by a user in the overlapping space are highly overlapped without flickering.

In some implementations of the present disclosure, based on related art, the same sub-pixel in the related art may be divided into two independent sub-pixels as a sub-pixel group PIXS; this can further simplify the design of the display panel.

For example, in the related art illustrated in FIG. 5-1, the sub-pixel arrangement is a strip RGB arrangement (strip RGB), which includes a red sub-pixel R, a green sub-pixel G, and a blue sub-pixel B. Each sub-pixel in FIG. 5-1 may be divided into a sub-pixel group PIXS (see FIG. 5-2), thereby obtaining an arrangement of the sub-pixel group PIXS in an implementation of the present disclosure. In the example of FIG. 5-2, each sub-pixel group PIXS includes a first sub-pixel PIXA located at a first direction D1 side and a second sub-pixel PIXB located at a second direction D2 side. The directions of the first direction D1 and the second direction D2 are opposite.

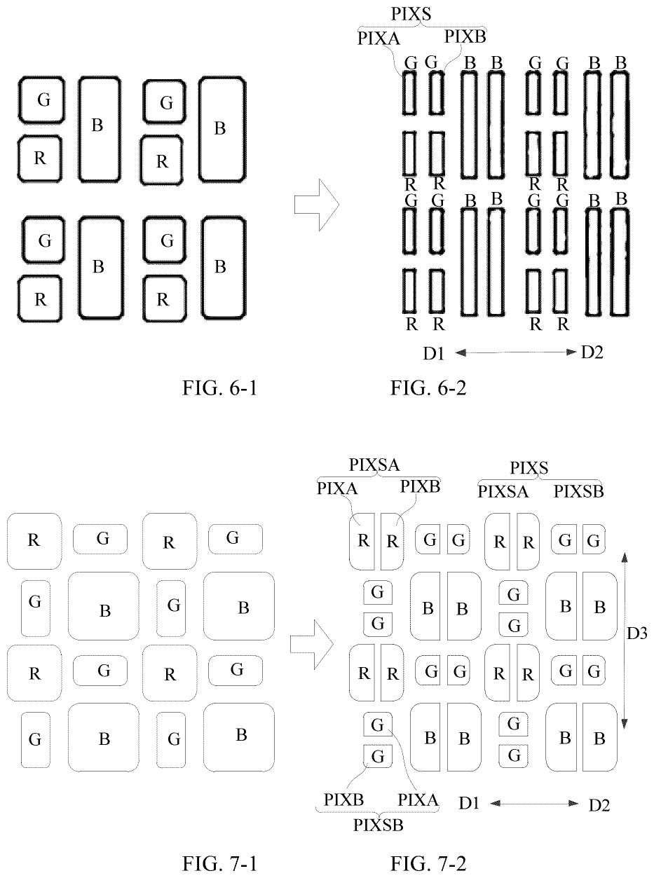

For another example, in the related art illustrated in FIG. 6-1, the sub-pixel arrangement is an SRGB arrangement, which includes a red sub-pixel R, a green sub-pixel G, and a blue sub-pixel B. Each sub-pixel in FIG. 6-1 may be divided into a sub-pixel group PIXS (see FIG. 6-2) to obtain an arrangement of the sub-pixel group PIXS in an implementation of the present disclosure. In the example of FIG. 6-2, each sub-pixel group PIXS includes a first sub-pixel PIXA located at a first direction D1 side and a second sub-pixel PIXB located at a second direction D2 side.

For another example, in the related art illustrated in FIG. 7-1, the sub-pixel arrangement is a blue diamond pixel arrangement, which includes a red sub-pixel R, a green sub-pixel G, and a blue sub-pixel B. Each sub-pixel in FIG. 7-1 may be divided into a sub-pixel group PIXS (see FIG. 7-2), thereby obtaining an arrangement of the sub-pixel group PIXS in an implementation of the present disclosure. In the example of FIG. 7-2, the sub-pixel groups PIXS include two types, namely, a first sub-pixel group PIXSA and a second sub-pixel group PIXSB. In the first sub-pixel group PIXSA, the first sub-pixel PIXA is located at a first direction D1 side of the second sub-pixel PIXB. In the second sub-pixel group PIXSB, the first sub-pixel PIXA is located at a third direction D3 side of the second sub-pixel PIXB. The first direction D1 and the third direction D3 are perpendicular to each other and are parallel to the plane where the display panel is located, for example, one is the row direction and the other is the column direction. In this way, it is possible to prevent the size of a single sub-pixel in a certain direction from being too small and difficult to prepare. In a further example, referring to FIG. 7-2, the green sub-pixels G form two different sub-pixel groups PIXS; the size of a first green sub-pixel group PIXSA in the first direction D1 is the same as the size of the second green sub-pixel group PIXSB in the third direction D3; the size of the first green sub-pixel group PIXSA in the third direction D3 is the same as the size of the second green sub-pixel group PIXSB in the first direction D1.

Of course, it is understandable that when the sub-pixel arrangement in the related art shown in FIG. 7-1 is improved to obtain the sub-pixel group PIXS arrangement of the implementation of the present disclosure, each sub-pixel can also be divided into a first sub-pixel PIXA located at a first direction D1 side and a second sub-pixel PIXB located at a second direction D2 side. In this way, each sub-pixel group PIXS of the display panel is the first sub-pixel group PIXSA.

It is understandable that the arrangements of the sub-pixel group PIXS illustrated in the above-mentioned FIG. 5-2, FIG. 6-2, and FIG. 7-2 are merely examples of the arrangements of the sub-pixel groups PIXS in the implementations of the present disclosure, and do not constitute limitations on the present disclosure. Obviously, in the implementations of the present disclosure, the sub-pixel groups PIXS may adopt other arrangements, which may refer to the arrangements of sub-pixels in the related art, or may be completely different from the arrangements of sub-pixels in the related art.

In some implementations of the present disclosure, a sub-pixel includes a pixel electrode, a light-emitting functional unit, and a common electrode layer COML which are sequentially stacked at a side of the driving layer F100 away from the base substrate BP. The light-emitting functional unit is a functional film layer that can emit light under the driving of the current provided by the pixel electrode and the common electrode layer COML; for example, it is a film layer combination between an anode and a cathode of a light-emitting element such as an OLED, PLED, or QLED, etc. For at least part of the sub-pixel groups PIXS, the light-emitting functional units of the first sub-pixel PIXA and the second sub-pixel PIXB may be interconnected into a whole, that is, there is no need to set a gap between the light-emitting functional unit of the first sub-pixel PIXA and the light-emitting functional unit of the second sub-pixel PIXB to separate the two. In this way, it is beneficial to reduce the preparation cost of the display panel and to improve the resolution of the display panel.

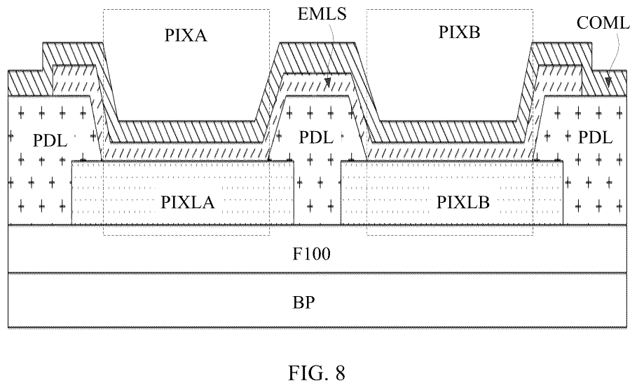

For example, referring to FIG. 8, the pixel electrode layer is provided with a pixel electrode PIXLA of the first sub-pixel PIXA and a pixel electrode PIXLB of the second sub-pixel PIXB. The pixel definition layer PDL has a first sub-pixel opening exposing at least part of a region of the pixel electrode PIXLA of the first sub-pixel PIXA and a second sub-pixel opening exposing at least part of a region of the pixel electrode PIXLB of the second sub-pixel PIXB. The light-emitting functional layer EML has a light-emitting functional unit group EMLS corresponding to the sub-pixel group PIXS, and the light-emitting functional unit group EMLS covers the first sub-pixel opening, the second sub-pixel opening, and covers a region between the first sub-pixel opening and the second sub-pixel opening. In this way, when preparing the light-emitting functional unit of the first sub-pixel PIXA and the light-emitting functional unit of the second sub-pixel PIXB, the light-emitting functional unit group EMLS can be directly prepared instead of preparing the light-emitting functional unit of the first sub-pixel PIXA and the light-emitting functional unit of the second sub-pixel PIXB separately, which can reduce the requirement for the resolution capability of the preparation equipment and the requirement for the preparation accuracy, and thus sub-pixel groups PIXS with a smaller size and a higher density can be prepared, thereby improving the resolution of the display panel and reducing the preparation cost. In the implementation, the part of the light-emitting functional unit group EMLS overlapping with the pixel electrode PIXLA exposed by the first pixel opening may serve as the light-emitting functional unit of the first sub-pixel PIXA, and the part of the light-emitting functional unit group EMLS overlapping with the pixel electrode PIXLB exposed by the second pixel opening may serve as the light-emitting functional unit of the second sub-pixel PIXB, and the remaining part of the light-emitting functional unit group EMLS may run across the surface of the pixel definition layer between the first pixel opening and the second pixel opening without being removed during the patterning process.

In a further example, the light-emitting device is an OLED. In this example, a fine metal mask may be used when the organic light-emitting layer in the light-emitting functional layer EML is formed by evaporation. However, the evaporation holes of the fine metal mask correspond one to one to the sub-pixel groups PIXS, rather than corresponding one to one to the sub-pixels. On the one hand, this reduces the precision requirements for the fine metal mask, especially reducing the size requirements for the evaporation holes, which can greatly reduce the cost of the fine metal mask. On the other hand, this enable fabrication of sub-pixels of smaller size, overcoming the limitation imposed by the size of the evaporation holes of the fine metal mask on the size of a single sub-pixel, thereby facilitating improving the resolution of the display panel.

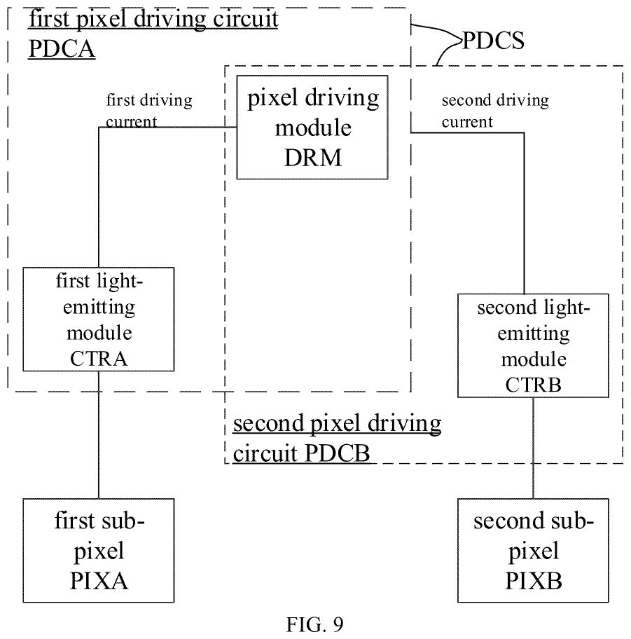

In some implementations of the present disclosure, referring to FIG. 9, the driving layer F100 has pixel driving circuit groups PDCS corresponding to the sub-pixel groups PIXS one to one, and the pixel driving circuit groups PDCS include a first pixel driving circuit PDCA for driving the first sub-pixel PIXA and a second pixel driving circuit PDCB for driving the second sub-pixel PIXB. The first pixel driving circuit PDCA and the second pixel driving circuit PDCB share a part of transistors. In this way, the layout area of the pixel driving circuit groups PDCS can be reduced, thereby avoiding the influence imposed by the layout area of the pixel driving circuit groups PDCS on the arrangement density of the first sub-pixel PIXA and the second sub-pixel PIXB, which is conducive to improving the resolution of the display panel.

In an implementation of the present disclosure, a pixel driving circuit group PDCS includes a pixel driving module DRM, a first light-emitting control module CTRA and a second light-emitting control module CTRB. The pixel driving module DRM is configured to provide a driving current. The first light-emitting control module CTRA is configured to, in response to a first light-emitting control signal EM1, cause the driving current to flow to the first sub-pixel PIXA. The second light-emitting control module CTRB is configured to, in response to a second light-emitting control signal EM2, cause the driving current to flow to the second sub-pixel PIXB. The pixel driving module DRM and the first light-emitting control module CTRA together serve as a first pixel driving circuit PDCA for driving the first sub-pixel PIXA. The pixel driving module DRM and the second light-emitting control module CTRB together serve as a second pixel driving circuit PDCB for driving the second sub-pixel PIXB. In the implementation, the pixel driving circuit group PDCS can realize driving of the first sub-pixel PIXA and the second sub-pixel PIXB in a time division manner. For example, at a first moment, the pixel driving module DRM provides the first driving current and the first light-emitting control module CTRA is turned on and the second light-emitting control module CTRB is turned off, so that the first sub-pixel PIXA can be driven while the second sub-pixel PIXB remains in a dark state. At a second moment, the pixel driving module DRM provides the second driving current and the second light-emitting control module CTRB is turned on and the first light-emitting control module CTRA is turned off, so that the second sub-pixel PIXB can be driven while the first sub-pixel PIXA remains in a dark state.

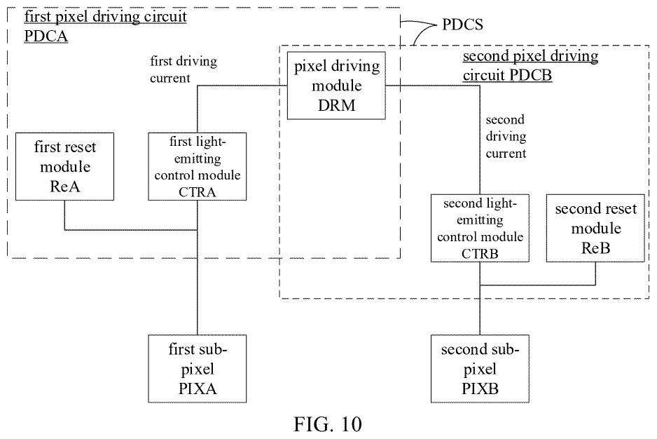

Further, referring to FIG. 10, the pixel driving circuit group PDCS may further include a first reset module ReA and a second reset module ReB. The first reset module ReA is configured to reset a voltage on a pixel electrode of the first sub-pixel PIXA in response to a first electrode reset signal Rel. The second reset module ReB is configured to reset a voltage on a pixel electrode of the second sub-pixel PIXB in response to a second electrode reset signal Re2. In this way, the driving effect of each sub-pixel can be further improved, and the image quality can be improved. In the implementation, the first pixel driving circuit PDCA may include the pixel driving module DRM, the first light-emitting control module CTRA and the first reset module ReA. The second pixel driving circuit PDCB may include the pixel driving module DRM, the second light-emitting control module CTRB and the second reset module ReB.

It is understandable that FIG. 9 and FIG. 10 only illustrate some feasible schemes of the pixel driving circuit group PDCS in the implementations of the present disclosure. In other implementations of the present disclosure, the pixel driving circuit group PDCS may also adopt other structures or architectures to achieve the driving of the first sub-pixel PIXA and the second sub-pixel PIXB respectively, and the first sub-pixel PIXA and the second sub-pixel PIXB may be driven simultaneously or in a time division manner.

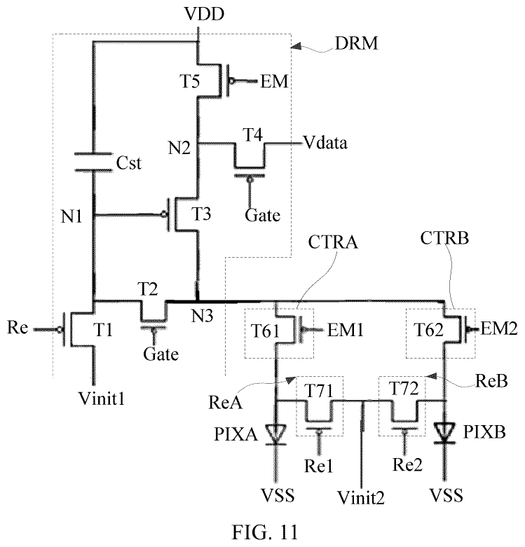

As follows, taking the architecture of the pixel driving circuit group PDCS illustrated in FIG. 11 as an example, a first example implementation of the pixel driving circuit group PDCS is described as an example.

In the first example implementation, referring to FIG. 11, the first pixel driving circuit PDCA and the second pixel driving circuit PDCB are both 7T1C (7 transistors+1 capacitor) circuits. In this example, the pixel driving circuit group PDCS includes a capacitor reset transistor T1, a threshold compensation transistor T2, a driving transistor T3, a data writing transistor T4, a current control transistor T5, a first light-emitting control transistor T61, a second light-emitting control transistor T62, a first electrode reset transistor T71, a second electrode reset transistor T72, and a storage capacitor Cst.

The storage capacitor Cst and the capacitor reset transistor T1, the threshold compensation transistor T2, the driving transistor T3, the data writing transistor T4, and the current control transistor T5 are used as devices in the pixel driving module DRM. A second terminal TIS of the capacitor reset transistor is used to apply a first initialization voltage Vinit1, a first terminal TID of the capacitor reset transistor is electrically connected to a first node N1, and a gate T1G of the capacitor reset transistor is used to apply a capacitor reset signal Re. In this way, the capacitor reset transistor T1 is used to apply the first initialization voltage Vinitl to the first node N1 in response to the capacitor reset signal Re, so as to realize resetting of the first initialization voltage Vinit1. A second terminal T2S of the threshold compensation transistor is electrically connected to a third node N3, a first terminal T2D of the threshold compensation transistor is electrically connected to the first node N1, and a gate T2G of the threshold compensation transistor is used to apply a scan signal Gate. The threshold compensation transistor T2 is used to, in response to the scan signal Gate, enable electrical conduction between the first node N1 and the third node N3. A second terminal T3S of the driving transistor is electrically connected to a second node N2, a first terminal T3D of the driving transistor is electrically connected to the third node N3, and a gate T3G of the driving transistor is electrically connected to the first node N1. The driving transistor T3 is used to control the magnitude of the output driving current under the control of the voltage of the first node N1. A second terminal T4S of the data writing transistor is used to apply a data voltage Vdata, a first terminal T4D of the data writing transistor is electrically connected to the second node N2, and a gate T4G of the data writing transistor is used to apply the scan signal Gate. The data writing transistor T4 is used to apply the data voltage Vdata to the second node N2 in response to the scan signal Gate. A second terminal T5S of the current control transistor is used to apply the driving power supply voltage VDD, a first terminal T5D of the current control transistor is electrically connected to the second node N2, and a gate T5G of the current control transistor is used to apply a current control signal EM. The current control transistor T5 is used to apply the driving power supply voltage VDD to the second node N2 under the control of the current control signal EM.

The operation of the pixel driving module DRM may be divided into the following three different stages: a circuit reset stage, a data writing stage and a current generation stage. In the circuit reset stage, the capacitor reset transistor T1, in response to the capacitor reset signal Re, resets the first node N1. This causes the driving transistor T3 to be turned on under the control of the first initialization voltage Vinit1. In the data writing stage, the threshold compensation transistor T2 and the data writing transistor T4 are turned on in response to the scan signal Gate, and this causes the data voltage Vdata to be applied to the second node N2 and charged to the first node N1 through the driving transistor T3 and the threshold compensation transistor T2 until the voltage of the first node N1 rises to make the driving transistor T3 be turned off. In this way, the voltage at the first node N1 is related to the data voltage Vdata and the threshold voltage of the driving transistor T3, realizing the writing of the data voltage Vdata and the compensation of the threshold voltage of the driving transistor T3. In the current generation stage, the current control transistor T5 is turned on in response to the current control signal EM. At this time, if one of the first light-emitting control transistor T61 and the second light-emitting control transistor T62 is also turned on, the driving transistor T3 can generate a corresponding driving current according to the voltage of the first node N1, thereby driving the first sub-pixel PIXA or the second sub-pixel PIXB to emit light.

In this example, the first light-emitting control transistor T61 may be used as the first light-emitting control module CTRA. A second terminal T61S of the first light-emitting control transistor is electrically connected to the third node N3, a first terminal T61D of the first light-emitting control transistor is electrically connected to a pixel electrode of the first sub-pixel PIXA, and a gate T61G of the first light-emitting control transistor is used to apply the first light-emitting control signal EM1. The first light-emitting control transistor T61 is used to enable electrical conduction between the third node N3 and the first sub-pixel PIXA in response to the first light-emitting control signal EM1. Further, the applying time of the first light-emitting control signal EM1 may partially overlap with the applying time of the current control signal EM, and a time period in which the applying time of the first light-emitting control signal EM1 overlaps with the applying time of the current control signal EM is a first time period, and the pixel driving module DRM generates a first driving current during the first time period, and the first driving current drives the first sub-pixel PIXA through the first light-emitting control transistor T61.

In this example, the second light-emitting control transistor T62 may be used as the second light-emitting control module CTRB. A second terminal T62S of the second light-emitting control transistor is electrically connected to the third node N3, a first terminal T62D of the second light-emitting control transistor is electrically connected to a pixel electrode of the second sub-pixel PIXB, and a gate T62G of the second light-emitting control transistor is used to apply the second light-emitting control signal EM2. The second light-emitting control transistor T62 is used to enable electrical conduction between the third node N3 and the second sub-pixel PIXB in response to the second light-emitting control signal EM2. Further, the applying time of the second light-emitting control signal EM2 may partially overlap with the applying time of the current control signal EM, and a time period in which the two overlap is a second time period, and the pixel driving module DRM generates a second driving current in the second time period, and the second driving current drives the second sub-pixel PIXB through the second light-emitting control transistor T62. Further, the applying time of the first light-emitting control signal EM1 and the applying time of the second light-emitting control signal EM2 do not overlap, so as to avoid the first sub-pixel PIXA and the second sub-pixel PIXB emitting light at the same time.

In this example, the first electrode reset transistor T71 may be used as the first reset module ReA. A second terminal T71S of the first electrode reset transistor is used to apply the second initialization voltage Vinit2, a first terminal T71D of the first electrode reset transistor is electrically connected to the pixel electrode of the first sub-pixel PIXA, and a gate T71G of the first electrode reset transistor is used to apply the first electrode reset signal Rel. The first electrode reset transistor T71 is used to, in response to the first electrode reset signal Rel, apply the second initialization voltage Vinit2 to the pixel electrode of the first sub-pixel PIXA, thereby resetting the pixel electrode of the first sub-pixel PIXA. In some possible implementations, the first initialization voltage Vinitl and the second initialization voltage Vinit2 may be the same initialization voltage; alternatively, they can also be different initialization voltages. In some possible implementations, the first electrode reset signal Rel and the capacitor reset signal Re may be the same reset control signal; alternatively, they can also be different reset control signals. In some possible implementations, the reset time of the capacitor reset transistor T1 and the reset time of the first electrode reset transistor T71 may overlap or partially overlap; alternatively, the capacitor reset transistor T1 and the first electrode reset transistor T71 may also be reset successively, and their reset times may not overlap.

In this example, the second electrode reset transistor T72 may be used as the second reset module ReB. A second terminal T72S of the second electrode reset transistor is used to apply the second initialization voltage Vinit2, a first terminal T72D of the second electrode reset transistor is electrically connected to the pixel electrode of the second sub-pixel PIXB, and a gate T72G of the second electrode reset transistor is used to apply the second electrode reset signal Re2. The second electrode reset transistor T72 is used to, in response to the second electrode reset signal Re2, apply the second initialization voltage Vinit2 to the pixel electrode of the second sub-pixel PIXB, thereby resetting the pixel electrode of the second sub-pixel PIXB. In some possible implementations, the second electrode reset signal Re2 and the capacitor reset signal Re may be the same reset control signal; alternatively, they can also be different reset control signals. In some possible implementations, the reset time of the capacitor reset transistor T1 and the reset time of the second electrode reset transistor T72 may overlap or partially overlap; alternatively, the capacitor reset transistor T1 and the second electrode reset transistor T72 may also be reset successively, and their reset times may not overlap.

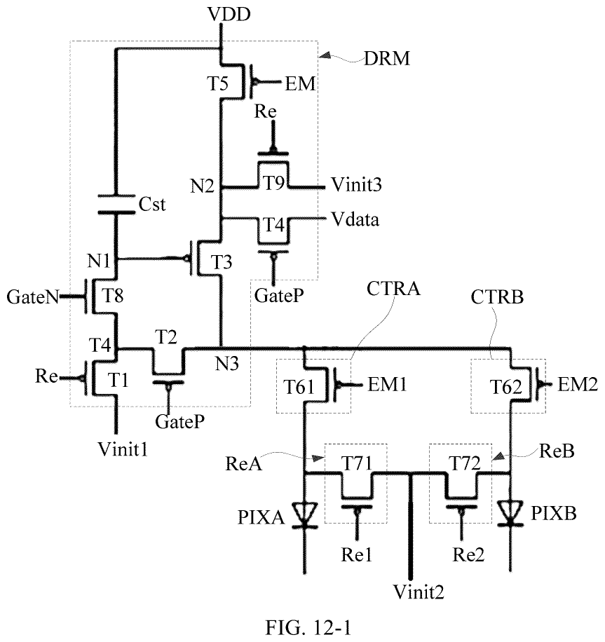

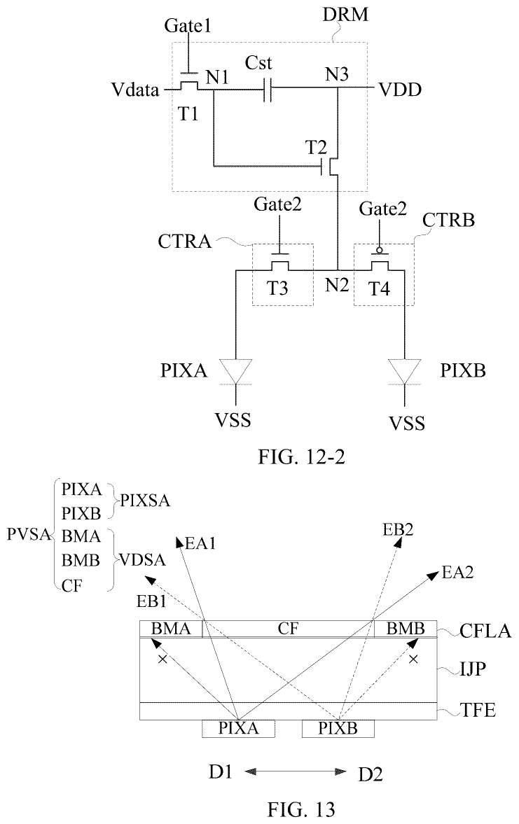

As follows, taking the architecture of the pixel driving circuit group PDCS illustrated in FIG. 12-1 as an example, a second example implementation of the pixel driving circuit group PDCS is described as an example.

In the second example implementation, the first pixel driving circuit PDCA and the second pixel driving circuit PDCB are both 9T1C (9 transistors+1 capacitor) circuits. In this example, the pixel driving circuit group PDCS includes a capacitor reset transistor T1, a threshold compensation transistor T2, a driving transistor T3, a data writing transistor T4, a current control transistor T5, a first light-emitting control transistor T61, a second light-emitting control transistor T62, a first electrode reset transistor T71, a second electrode reset transistor T72, a pressure maintenance transistor T8, a source reset transistor T9 and a storage capacitor Cst.

The storage capacitor Cst and the capacitor reset transistor T1, the threshold compensation transistor T2, the driving transistor T3, the data writing transistor T4, the current control transistor T5, the pressure maintenance transistor T8, and the source reset transistor T9 are used as devices in the pixel driving module DRM. A second terminal TIS of the capacitor reset transistor is used to apply a first initialization voltage Vinit1, a first terminal TID of the capacitor reset transistor is electrically connected to a fourth node N4, and a gate T1G of the capacitor reset transistor is used to apply a capacitor reset signal Re. In this way, the capacitor reset transistor T1 is used to apply the first initialization voltage Vinit1 to the fourth node N4 in response to the capacitor reset signal Re. A second terminal T2S of the threshold compensation transistor is electrically connected to a third node N3, a first terminal T2D of the threshold compensation transistor is electrically connected to the fourth node N4, and a gate T2G of the threshold compensation transistor is used to apply a second scan signal GateP. The threshold compensation transistor T2 is used to, in response to the second scan signal GateP, enable electrical conduction between the fourth node N4 and the third node N3. A second terminal T3S of the driving transistor is electrically connected to a second node N2, a first terminal T3D of the driving transistor is electrically connected to the third node N3, and a gate T3G of the driving transistor is electrically connected to a first node N1. The driving transistor T3 is used to control the magnitude of the output driving current under the control of the voltage of the first node N1. A second terminal T4S of the data writing transistor is used to apply a data voltage Vdata, a first terminal T4D of the data writing transistor is electrically connected to a second node N2, and a gate T4G of the data writing transistor is used to apply a second scan signal GateP. The data writing transistor T4 is used to apply the data voltage Vdata to the second node N2 in response to the second scan signal GateP. A second terminal T5S of the current control transistor is used to apply a driving power supply voltage VDD, a first terminal T5D of the current control transistor is electrically connected to the second node N2, and a gate T5G of the current control transistor is used to apply a current control signal EM. The current control transistor T5 is used to apply the driving power supply voltage VDD to the second node N2 under the control of the current control signal EM. A second terminal T8S of the pressure maintenance transistor is electrically connected to the fourth node N4, a first terminal T8D of the pressure maintenance transistor is electrically connected to the first node N1, and a gate T8G of the pressure maintenance transistor is used to apply a first scan signal GateN. The pressure maintenance transistor T8 is used to enable electrical conduction between the first node N1 and the fourth node N4 under the control of the first scan signal GateN. A second terminal T9S of the source reset transistor is used to apply a third initialization voltage Vinit3, a first terminal T9D of the source reset transistor is electrically connected to the second node N2, and a gate T9G of the source reset transistor is used to apply the capacitor reset signal Re. The source reset transistor T9 is used to apply the third initialization voltage Vinit3 to the second node N2 under the control of the capacitor reset signal Re.

The operation of the pixel driving module DRM may be divided into the following three different stages: a circuit resetting stage, a data writing stage and a current generating stage.

In the circuit reset stage, the pressure maintenance transistor T8, in response to the first scan signal GateN, enables electrical conduction between the first node N1 and the fourth node N4. The capacitor reset transistor T1 is turned on in response to the capacitor reset signal Re, so that the first initialization voltage Vinitl is applied to the first node N1 and the fourth node N4, and the first node N1 is reset. This makes the driving transistor T3 turned on under the control of the first initialization voltage Vinit1. At the same time, the source reset transistor T9 is turned on in response to the capacitor reset signal Re, so that the third initialization voltage Vinit3 is applied to the second node N2 to reset the second node N2. At the same time, since the driving transistor T3 is turned on, the third initialization voltage Vinit3 may also be applied to the third node N3 to reset the third node N3.

In the data writing stage, the pressure maintenance transistor T8, in response to the first scan signal GateN, enables electrical conduction between the first node N1 and the fourth node N4. The threshold compensation transistor T2 and the data writing transistor T4 are turned on in response to the second scan signal GateP, so that the data voltage Vdata is applied to the second node N2 and charged to the first node N1 through the driving transistor T3, the threshold compensation transistor T2 and the pressure maintenance transistor T8, until the voltage of the first node N1 rises to make the driving transistor T3 be turned off. In this way, the voltage at the first node N1 is related to the data voltage Vdata and the threshold voltage of the driving transistor T3, realizing the writing of the data voltage Vdata and the compensation of the threshold voltage of the driving transistor T3.

In the current generation stage, the current control transistor T5 is turned on in response to the current control signal EM, and the pressure maintenance transistor T8 is turned off with the first scan signal GateN being not applied. At this time, if one of the first light-emitting control transistor T61 and the second light-emitting control transistor T62 is also turned on, the driving transistor T3 may generate a corresponding driving current according to the voltage of the first node N1, thereby driving the first sub-pixel PIXA or the second sub-pixel PIXB to emit light. Furthermore, the pressure maintenance transistor T8 may be a metal oxide semiconductor transistor, which makes the leakage current of the pressure maintenance transistor T8 smaller in the off state, which is conducive to maintaining the voltage of the first node N1. Accordingly, the first scan signal GateN is a high-level signal.

In the second example implementation, the functions of the first light-emitting control transistor T61, the second light-emitting control transistor T62, the first electrode reset transistor T71, and the second electrode reset transistor T72 are the same or substantially the same as those in the first example implementation, and are not described again.

In some implementations of the present disclosure, one of the first light-emitting control module CTRA and the second light-emitting control module CTRB is an N-type transistor, and the other is a P-type transistor; a gate of the N-type transistor and a gate of the P-type transistor are connected to a same light-emitting control signal line. The light-emitting control signal line can be applied with a light-emitting control signal. The light-emitting control signal has a high-level signal and a low-level signal that are alternately set. One of the high-level signal and the low-level signal is used as the first light-emitting control signal EM1, and the other is used as the second light-emitting control signal EM2. The high-level signal may turn on the N-type transistor and turn off the P-type transistor. The low-level signal can turn on the P-type transistor and turn off the N-type transistor.

For example, the first light-emitting control transistor T61 is a P-type transistor and the second light-emitting control transistor T62 is an N-type transistor. The gate T61G of the first light-emitting control transistor and the gate T62G of the second light-emitting control transistor are connected to the same light-emitting control signal line, and the light-emitting control signal line is applied with a light-emitting control signal. The light-emitting control signal has a high-level signal and a low-level signal that are alternately set. The low-level signal of the light-emitting control signal is used as the first light-emitting control signal EM1 to turn on the first light-emitting control transistor T61 and turn off the second light-emitting control transistor T62. The high-level signal of the light-emitting control signal is used as the second light-emitting control signal EM2 to turn on the second light-emitting control transistor T62 and turn off the first light-emitting control transistor T61.

In a third example implementation, referring to FIG. 12-2, the first pixel driving circuit PDCA and the second pixel driving circuit PDCB are both 3T1C (3 transistors+1 capacitor) circuits. In this example, the pixel driving circuit group PDCS includes a data writing transistor T1, a driving transistor T2, a first light-emitting control transistor T3, a second light-emitting control transistor T4, and a storage capacitor Cst.

The storage capacitor Cst and the data writing transistor T1 and the driving transistor T2 are used as devices in the pixel driving module DRM. A second terminal TIS of the data writing transistor is used to apply a data voltage Vdata, a first terminal TID of the data writing transistor is electrically connected to a first node N1, and a gate T1G of the data writing transistor is used to apply a first scan signal Gate1. The data writing transistor T1 is used to apply the data voltage Vdata to the first node N1 in response to the first scan signal Gate1. One terminal of the storage capacitor Cst is connected to the first node N1, and the other terminal is electrically connected to a third node N3, and the third node N3 is used to apply a driving power supply voltage VDD. A second terminal T2S of the driving transistor is electrically connected to the third node N3, a first terminal T2D of the driving transistor is electrically connected to a second node N2, and a gate T2G of the driving transistor is electrically connected to the first node N1. The driving transistor T2 is used to control the magnitude of the output driving current under the control of the voltage of the first node N1.

The first light-emitting control transistor T3 serves as the first light-emitting control module CTRA of the pixel driving circuit group PDCS. A second terminal T3S of the first light-emitting control transistor is connected to the second node N2, a first terminal T3D of the first light-emitting control transistor is electrically connected to a pixel electrode of the first sub-pixel PIXA, and a gate T3G of the first light-emitting control transistor is used to apply a second scan signal Gate2. The second light-emitting control transistor T4 serves as the second light-emitting control module CTRB of the pixel driving circuit group PDCS. A second terminal T4S of the second light-emitting control transistor is connected to the second node N2, a first terminal T4D of the second light-emitting control transistor is electrically connected to a pixel electrode of the second sub-pixel PIXB, and a gate T4G of the second light-emitting control transistor is used to apply the second scan signal Gate2.

The first light-emitting control transistor T3 and the second light-emitting control transistor T4 are thin film transistors of opposite types. Specifically, one of the first light-emitting control transistor T3 and the second light-emitting control transistor T4 is an N-type transistor and the other is a P-type transistor. The gate T3G of the first light-emitting control transistor and the gate T4G of the second light-emitting control transistor are connected with the same scan line, and the scan line is used to apply the second scan signal Gate2. When the second scan signal Gate2 is a high-level signal, the N-type transistor is turned on and the P-type transistor is turned off. When the second scan signal Gate2 is a low-level signal, the N-type transistor is turned off and the P-type transistor is turned on. In this way, by controlling the high and low levels of the second scan signal Gate2, either the first light-emitting control transistor T3 or the second light-emitting control transistor T4 can be selectively turned on, thereby realizing the selective light emission of one of the first sub-pixel PIXA and the second sub-pixel PIXB, and thus realizing the driving of the first sub-pixel PIXA and the second sub-pixel PIXB in a time division manner.

In an implementation of the present disclosure, referring to FIG. 1 and FIG. 2, the viewing-angle definition layer VDL defines the light transmission space of the first sub-pixel PIXA and the second sub-pixel PIXB. In the present disclosure, a boundary of the light exit projection space VA of the first sub-pixel PIXA at a first direction D1 side is used as a first boundary EA1 of the light exit projection space VA of the first sub-pixel PIXA (referred to as boundary EA1 in the present disclosure), and a boundary of the light exit projection space VA of the first sub-pixel PIXA at the second direction D2 side is used as a second boundary EA2 of the light exit projection space of the first sub-pixel PIXA (referred to as boundary EA2 in the present disclosure). When a user is between the boundary EA1 and the boundary EA2, the user is in the light exit projection space VA of the first sub-pixel PIXA and can see the first image displayed by the first sub-pixel PIXA. A boundary of the light exit projection space VB of the second sub-pixel PIXB at a first direction D1 side is used as a first boundary EB1 of the light exit projection space VB of the second sub-pixel PIXB (referred to as boundary EB1 in the present disclosure), and a boundary of the light exit projection space VB of the second sub-pixel PIXB at a second direction D2 side is used as a second boundary EB2 of the light exit projection space VB of the second sub-pixel PIXB (referred to as boundary EB2 in the present disclosure). When the user is between the boundary EB1 and the boundary EB2, the user is in the light exit projection space VB of the second sub-pixel PIXB and can see the second image displayed by the second sub-pixel PIXB.

In an implementation of the present disclosure, the viewing-angle definition layer VDL may adopt a scheme of black matrix+color film to realize the definition of the light exit projection space VA of the first sub-pixel PIXA and the light exit projection space VB of the second sub-pixel PIXB. For example, one of the light exit projection space VA of the first sub-pixel PIXA and the light exit projection space VB of the second sub-pixel PIXB is at least partially at the first direction D1 side of the display panel, and the other is at least partially at the second direction D2 side of the display panel.

In some implementations of the present disclosure, referring to FIG. 13, the viewing-angle definition layer VDL includes a light-transmitting medium layer IJP and a first color filter layer CFLA which are sequentially stacked at a side of the pixel layer F200 away from the base substrate BP. The first color filter layer CFLA includes viewing-angle definition structures VDS corresponding the sub-pixel groups PIXS one to one. The sub-pixel groups PIXS and the corresponding viewing-angle definition structures VDS form light exit units.

In an implementation, the light-transmitting medium layer IJP may be a light-transmitting organic material layer, an inorganic material layer, or a composite film layer of an organic material layer and an inorganic material layer. In an example, the light-transmitting medium layer IJP may be an organic material layer, which may be formed by a printing technology.

In an implementation, the light exit units include a first light exit unit PVSA. The sub-pixel group PIXS in the first light exit unit PVSA is a first sub-pixel group PIXSA, and the viewing-angle definition structure VDS in the first light exit unit PVSA is a first viewing-angle definition structure VDSA. In the first light exit unit PVSA, the first sub-pixel PIXA is located at a first direction D1 side of the second sub-pixel PIXB. The first viewing-angle definition structure VDSA includes a first light-shielding portion BMA corresponding to the first sub-pixel PIXA, a second light-shielding portion BMB corresponding to the second sub-pixel PIXB, and a color resist unit CF between the first light-shielding portion BMA and the second light-shielding portion BMB. The color of the color resist unit CF is the same as the light-emitting color of the sub-pixel group PIXS. An orthographic projection of the first light-shielding portion BMA on the base substrate BP is at least partially located at a first direction D1 side of an orthographic projection of the first sub-pixel PIXA on the base substrate BP, and the first light-shielding portion BMA exposes at least part of the first sub-pixel PIXA. An orthographic projection of the second light-shielding portion BMB on the base substrate BP is at least partially located at a second direction D2 side of an orthographic projection of the second sub-pixel PIXB on the base substrate BP, and the second light-shielding portion BMB exposes at least part of the second sub-pixel PIXB. The first direction DI is opposite to the second direction D2.

Referring to FIG. 13, in the first light exit unit PVSA, the light emitted by the first sub-pixel PIXA and the second sub-pixel PIXB is emitted from the color resist unit CF and is shielded by the first light-shielding portion BMA and the second light-shielding portion BMB. In this example, the first light-shielding portion BMA is not located directly above the first sub-pixel PIXA (in the direction away from the base substrate BP), but is offset towards the first direction D1 side. This makes the light exit projection space VA of the first sub-pixel PIXA mainly be oriented towards the second direction D2 side. Correspondingly, the second light-shielding portion BMB is not located directly above the second sub-pixel PIXB (in the direction away from the base substrate BP), but is offset towards the second direction D2 side. This makes the light exit projection space VB of the second sub-pixel PIXB mainly be oriented towards the first direction D1 side. Therefore, in front of the display panel, the light exit projection space VA of the first sub-pixel PIXA and the light exit projection space VB of the second sub-pixel PIXB may be at least partially separated. In at least a part of the region at the first direction D1 side in front of the display panel, the user can see the second image displayed by the second sub-pixel PIXB, but cannot see the first image displayed by the first sub-pixel PIXA. In at least part of the region at the second direction D2 side in front of the display panel, the user can see the first image displayed by the first sub-pixel PIXA, but cannot see the second image displayed by the second sub-pixel PIXB.

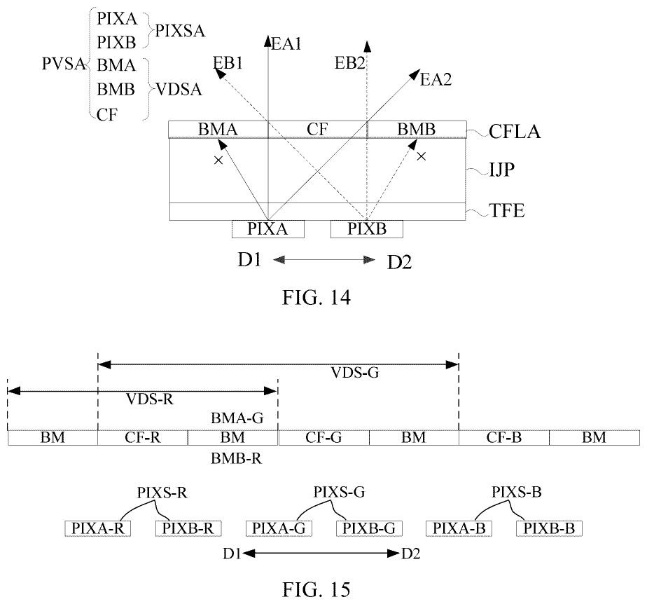

In an implementation, the light exit projection space VA of the first sub-pixel PIXA and the light exit projection space VB of the second sub-pixel PIXB may be adjusted by adjusting a distance between an inner edge of the first light-shielding portion BMA (the edge of the first light-shielding portion BMA at a side close to the second sub-pixel PIXB) and an inner edge of the first sub-pixel PIXA (the edge of the first sub-pixel PIXA at a side close to the second sub-pixel PIXB) in the first direction D1. Referring to FIG. 13 and FIG. 14, when the distance between the inner edge of the first light-shielding portion BMA and the inner edge of the first sub-pixel PIXA decreases, the angle between the boundary EA1 and the second direction D2 decreases, and the angle between the boundary EB1 and the second direction D2 also decreases.

In an implementation, the light exit projection space VA of the first sub-pixel PIXA and the light exit projection space VB of the second sub-pixel PIXB may be adjusted by adjusting a distance between an inner edge of the second light-shielding portion BMB (the edge of the second light-shielding portion BMB at a side close to the first sub-pixel PIXA) and an inner edge of the second sub-pixel PIXB (the edge of the second sub-pixel PIXB at a side close to the first sub-pixel PIXA) in the first direction D1. Referring to FIG. 13 and FIG. 14, when the distance between the inner edge of the second light-shielding portion BMB and the inner edge of the second sub-pixel PIXB decreases, the angle between the boundary EA2 and the first direction D1 decreases, and the angle between the boundary EB2 and the first direction D1 also decreases.

In an optional solution of the implementation, in at least part of first light exit units PVSA, the first sub-pixel PIXA partially overlaps with the first light-shielding portion BMA. The size of a part of the first sub-pixel PIXA overlapping with the first light-shielding portion BMA in the first direction D1 does not exceed half of the size of the first sub-pixel PIXA in the first direction D1. In this way, the first light-shielding portion BMA can effectively define the orientation of the boundary EA1 and the boundary EB1 to define the light exit projection space VA of the first sub-pixel PIXA and the light exit projection space VB of the second sub-pixel PIXB, and can also prevent the color resist unit CF from being too small in the first direction D1 (too small size of the color resistant unit may cause the brightness of the first sub-pixel PIXA and the second sub-pixel PIXB to be excessively reduced), so that the display panel maintains a suitable aperture ratio.

Furthermore, for any one first light exit unit PVSA, the first sub-pixel PIXA partially overlaps with the first light-shielding portion BMA, and the size of a part of the first sub-pixel PIXA overlapping with the first light-shielding portion BMA in the first direction DI does not exceed half of the size of the first sub-pixel PIXA in the first direction D1.

In an example, referring to FIG. 13, an orthographic projection of the inner edge of the first light-shielding portion BMA on the base substrate BP at least partially overlaps with an orthographic projection of an outer edge of the first sub-pixel PIXA (the edge of the first sub-pixel PIXA away from the second sub-pixel PIXB) on the base substrate BP.

In an example, referring to FIG. 14, an orthographic projection of a geometric center of the first sub-pixel PIXA on the base substrate BP is located on an orthographic projection of the inner edge of the first light-shielding portion BMA on the base substrate BP. In other words, the first sub-pixel PIXA is divided into a first part located at the first direction D1 side and a second part located at the second direction D2 side, and a boundary between the first part and the second part passes through the geometric center of the first sub-pixel PIXA. The first part of the first sub-pixel PIXA is shielded by the first light-shielding portion BMA, and the second part of the first sub-pixel PIXA is exposed by the first light-shielding portion BMA. In this example, the first light-shielding portion BMA has a relatively large size, which can make the light exit projection space VA of the first sub-pixel PIXA and the light exit projection space VB of the second sub-pixel PIXB better separated at the first direction D1 side of the display panel, and achieve better privacy protection effect at the first direction D1 side.

In an optional solution of the implementation, in at least part of first light exit units PVSA, the second sub-pixel PIXB partially overlaps with the second light-shielding portion BMB, and a size of a part of the second sub-pixel PIXB overlapping with the second light-shielding portion BMB in the first direction D1 does not exceed half of the size of the second sub-pixel PIXB in the first direction D1. In this way, the second light-shielding portion BMB can effectively define the orientation of the boundary EA2 and the boundary EB2 to define the light exit projection space VA of the first sub-pixel PIXA and the light exit projection space VB of the second sub-pixel PIXB, and can also prevent the color resist unit CF from having a too small size in the second direction D2 (the too small size of the color resist unit CF may causes the brightness of the first sub-pixel PIXA and the second sub-pixel PIXB to be excessively reduced), so that the display panel maintains a suitable aperture ratio.

Furthermore, for any one first light exit unit PVSA, the second sub-pixel PIXB partially overlaps with the second light-shielding portion BMB, and a size of a part of the second sub-pixel PIXB overlapping with the second light-shielding portion BMB in the second direction D2 does not exceed half of a size of the second sub-pixel PIXB in the first direction D1.

In an example, referring to FIG. 13, an orthographic projection of the inner edge of the second light-shielding portion BMB on the base substrate BP at least partially overlaps with the orthographic projection of the outer edge of the second sub-pixel PIXB (the edge of the second sub-pixel PIXB away from the first sub-pixel PIXA) on the base substrate BP.

In an example, referring to FIG. 14, an orthographic projection of a geometric center of the second sub-pixel PIXB on the base substrate BP is located on an orthographic projection of the inner edge of the second light-shielding portion BMB on the base substrate BP. In other words, the second sub-pixel PIXB is divided into a first part located at the second direction D2 side and a second part located at the first direction D1 side, and a boundary between the first part and the second part passes through the geometric center of the second sub-pixel PIXB. The first part of the second sub-pixel PIXB is shielded by the second light-shielding portion BMB, and the second part of the second sub-pixel PIXB is exposed by the second light-shielding portion BMB. In this example, the second light-shielding portion BMB has a relatively large size, which can make the light exit projection space VA of the first sub-pixel PIXA and the light exit projection space VB of the second sub-pixel PIXB better separated at the second direction D2 side of the display panel, and achieve better privacy protection effect at the second direction D2 side.

In an optional solution of the implementation, referring to FIG. 15, for two first light exit units PVSA which are adjacent along the first direction D1, a second light-shielding portion BMB of a first light exit unit PVSA located at the first direction D1 side is reused as a first light-shielding portion BMA of a first light exit unit PVSA located at the second direction D2 side. In other words, along the first direction D1, the first color filter layer CFLA may include light-shielding portions BM and color resist units CF that are alternately arranged in sequence; two adjacent light-shielding portions BM and a color resist unit CF between the two light-shielding portions BM may serve as a first viewing-angle definition structure VDSA corresponding to a first sub-pixel group PIXSA below the color resist unit CF (in the direction close to the base substrate BP). Therefore, for a light-shielding portion BM not at an end position, it may serve as a second light-shielding portion BMB of a first viewing-angle definition structure VDSA at the first direction D1 side, and may also serve as a first light-shielding portion BMA of a first viewing-angle definition structure VDSA at the second direction D2 side.

For example, in FIG. 15, along the second direction D2, the display panel includes a plurality of first sub-pixel groups PIXSA arranged in sequence, such as a red sub-pixel group PIXS-R, a green sub-pixel group PIXS-G, and a blue sub-pixel group PIXS-B arranged in sequence. The red sub-pixel group PIXS-R includes a first red sub-pixel PIXA-R located at the first direction D1 side and a second red sub-pixel PIXB-R located at the second direction D2 side. The green sub-pixel group PIXS-G includes a first green sub-pixel PIXA-G located at the first direction D1 side and a second green sub-pixel PIXB-G located at the second direction D2 side. The blue sub-pixel group PIXS-B includes a first blue sub-pixel PIXA-B located at the first direction D1 side and a second blue sub-pixel PIXB-B located at the second direction D2 side. The first color filter layer CFLA includes light-shielding portions BM and color resist units CF arranged alternately in sequence along the second direction D2. The color resist units CF are arranged in one-to-one correspondence with the sub-pixel groups PIXS, and the color resist units CF overlap with the corresponding sub-pixel groups PIXS and have the same color as the corresponding sub-pixel groups PIXS. For example, the color resist units CF include a red color resist unit CF-R corresponding to the red sub-pixel group PIXS-R, a green color resist unit CF-G corresponding to the green sub-pixel group PIXS-G, and a blue color resist unit CF-B corresponding to the blue sub-pixel group PIXS-B. A light-shielding portion BM at the first direction D1 side of the red color resist unit CF-R, a light-shielding portion BM at the second direction D2 side of the red color resist unit CF-R and the red color resist unit CF-R can form a viewing-angle definition structure VDS-R for the red sub-pixel group. The viewing-angle definition structure VDS-R for the red sub-pixel group corresponds to the red sub-pixel group PIXS-R to form a first light exit unit PVSA. A light-shielding portion BM at the first direction D1 side of the green color resist unit CF-G, a light-shielding portion BM at the second direction D2 side of the green color resist unit CF-G and the green color resist unit CF-G can form a viewing-angle definition structure VDS-G for the green sub-pixel group. The viewing-angle definition structure VDS-G for the green sub-pixel group corresponds to the green sub-pixel group PIXS-G to form a first light exit unit PVSA. A light-shielding portion BM between the red color resist unit CF-R and the green color resist unit CF-G can be used as the second light-shielding portion BMB (marked as BMB-R in FIG. 15) in the viewing-angle definition structure VDS-R for the red sub-pixel group, and can also be used as the first light-shielding portion BMA (marked as BMA-G in FIG. 15) in the viewing-angle definition structure VDS-G for the green sub-pixel group.

In an optional solution of the implementation, a distance between the first color filter layer CFLA and the pixel layer F200 is not smaller than a size of a first sub-pixel group PIXSA along the first direction D1. In the implementation of the present disclosure, the size of the first sub-pixel group PIXSA along the first direction D1 may refer to a distance between the outer edge of the first sub-pixel PIXA and the outer edge of the second sub-pixel PIXB in the first direction D1. In this way, it is possible to prevent the spacing between the first color filter layer CFLA and the driving layer F100 from being too small, better define the light exit projection space VA of the first sub-pixel PIXA and the light exit projection space VB of the second sub-pixel PIXB, prevent the angle between the boundary EAl and the second direction D2 from being too large, and prevent the angle between the boundary EB2 and the first direction D1 prevent being too large, and this is more conducive to the separation of the light exit projection space VA of the first sub-pixel PIXA and the light exit projection space VB of the second sub-pixel PIXB. It can be understood that when the sizes of the first light-shielding part BMA and the second light-shielding part BMB are fixed, the smaller the distance between the first color filter layer CFLA and the driving layer F100, the greater the overlap between the light exit projection space VA of the first sub-pixel PIXA and the light exit projection space VB of the second sub-pixel PIXB, and the more unfavorable it is for separating the light exit projection space VA of the first sub-pixel PIXA and the light exit projection space VB of the second sub-pixel PIXB.

In an optional solution of the implementation, referring to FIG. 16, the viewing-angle definition layer VDL further includes a first black matrix layer BML1 between the pixel layer F200 and the light-transmitting medium layer IJP. The first viewing-angle definition structure VDSA further includes a first bottom light-shielding portion BMAx and a second bottom light-shielding portion BMBx located in the first black matrix layer BML1. The first bottom light-shielding portion BMAx overlaps with the first light-shielding portion BMA, and the second bottom light-shielding portion BMBx overlaps with the second light-shielding portion BMB.

Thus, compared to the first light-shielding portion BMA, the first bottom light-shielding portion BMAx is closer to the first sub-pixel PIXA, which helps to better block the light at a wide viewing angle emitted by the first sub-pixel PIXA towards the first direction D1 side, and reduce the risk of light leakage of the first sub-pixel PIXA. Accordingly, the first image displayed by the first sub-pixel PIXA cannot be seen at a wide viewing angle at the first direction D1 side of the display panel. Similarly, compared to the second light-shielding portion BMB, the second bottom light-shielding portion BMBx is closer to the second sub-pixel PIXB, which helps to better block the light at the wide viewing angle emitted by the second sub-pixel PIXB towards the second direction D2 side, and reduce the risk of light leakage of the second sub-pixel PIXB. Accordingly, the second image displayed by the second sub-pixel PIXB cannot be seen at a wide viewing angle at the second direction D2 side of the display panel. In this way, the privacy protection effect of the display panel in the privacy mode can be improved.

Moreover, it can be understood that if the first sub-pixel PIXA has light leakage at a wide viewing angle towards the first direction D1 side, the user can see the first light leakage image presented by the light leakage at the first direction D1 side of the display panel, and the first light leakage image is superimposed with the second image, which causes the user to be unable to see a high-quality second image at the first direction D1 side of the display panel, thus reducing the display performance of the display panel at the first direction D1 side. Similarly, if the second sub-pixel PIXB has light leakage at a wide viewing angle towards the second direction D2 side, the user can see the second light leakage image presented by the light leakage at the second direction D2 side of the display panel, and the second light leakage image is superimposed with the first image, which causes the user to be unable to see a high-quality first image at the second direction D2 side of the display panel, thereby reducing the display performance of the display panel at the second direction D2 side. In an optional solution of the implementation, the first bottom light-shielding portion BMAx and the second bottom light-shielding portion BMBx can block the light leakage at the wide viewing angle, thereby reducing the risk of the first light leakage image and the second light leakage image, and improving the display performance of the display panel in the privacy mode. In an implementation of the present disclosure, a viewing angle refers to an angle at which the light deviates from the normal of the display panel in the first direction D1 or the second direction D2. The smaller the viewing angle, the more perpendicular the light is to the display panel; the larger the viewing angle, the smaller the angle between the light and the first direction D1 or the second direction D2.

Furthermore, an orthographic projection of the first bottom light-shielding portion BMAx on the base substrate BP does not exceed an orthographic projection of the first light-shielding portion BMA on the base substrate BP. An orthographic projection of the second bottom light-shielding portion BMBx on the base substrate BP does not exceed an orthographic projection of the second light-shielding portion BMB on the base substrate BP.

In an example, the orthographic projection of the first light-shielding portion BMA on the base substrate BP coincides with the orthographic projection of the first bottom light-shielding portion BMAx on the base substrate BP. The orthographic projection of the second light-shielding portion BMB on the base substrate BP coincides with the orthographic projection of the second bottom light-shielding portion BMBx on the base substrate BP. In this way, a mask for preparing the first black matrix layer BML1 may be applied to the preparation process of the first color filter layer CFLA, which can reduce the number of masks required in the preparation process of the display panel, thereby reducing the preparation cost of the display panel. Alternatively, in other examples of the present disclosure, the shape or size of the first light-shielding portion BMA or the orthographic projection position of the first light-shielding portion BMA on the base substrate BP may not be completely consistent with that of the first bottom light-shielding portion BMAx; the shape or size of the second light-shielding portion BMB or the orthographic projection position of the second light-shielding portion BMB on the base substrate BP may not be completely consistent with that of the second bottom light-shielding portion BMBx.

In some implementations of the present disclosure, the viewing-angle definition layer VDL includes a light-transmitting medium layer IJP and a first color filter layer CFLA which are sequentially stacked at a side of the pixel layer F200 away from the base substrate BP. The first color filter layer CFLA includes viewing-angle definition structures VDS corresponding one to one to the sub-pixel groups PIXS. The sub-pixel groups PIXS and the corresponding viewing-angle definition structures VDS constitute light exit units.

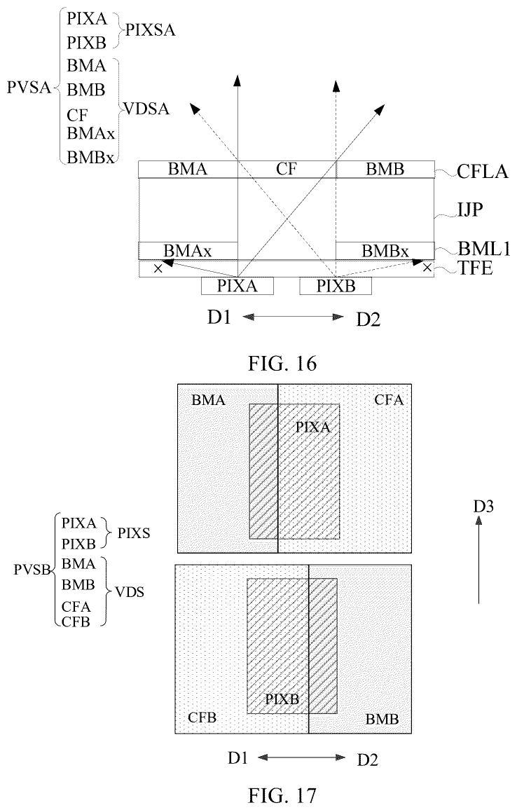

In an implementation, referring to FIG. 17, the light exit units include a second light exit unit PVSB. The second light exit unit PVSB includes a second sub-pixel group PIXSB and a second viewing-angle definition structure VDSB corresponding to the second sub-pixel group PIXSB. In the second light exit unit PVSB, the first sub-pixel PIXA is located at the third direction D3 side of the second sub-pixel PIXB. The third direction D3 is perpendicular to the first direction D1 and parallel to a plane where the display panel is located. The second viewing-angle definition structure VDSB includes a first light-shielding portion BMA and a first color resist unit CFA corresponding to the first sub-pixel PIXA, and a second light-shielding portion BMB and a second color resist unit CFB corresponding to the second sub-pixel PIXB. The colors of the first color resist unit CFA and the second color resist unit CFB are the same as the light-emitting color of the sub-pixel group PIXS. An orthographic projection of the first light-shielding portion BMA on the base substrate BP is at least partially located at the first direction D1 side of an orthographic projection of the first sub-pixel PIXA on the base substrate BP, and the first light-shielding portion BMA exposes at least part of the first sub-pixel PIXA. An orthographic projection of the first color resist unit CFA on the base substrate BP is at least partially located at the second direction D2 side of the orthographic projection of the first sub-pixel PIXA on the base substrate BP, and the first color resist unit CFA extends along the first direction D1 to be connected with the first light-shielding portion BMA. An the orthographic projection of the second light-shielding portion BMB on the base substrate BP is at least partially located at the second direction D2 side of an orthographic projection of the second sub-pixel PIXB on the base substrate BP, and the second light-shielding portion BMB exposes at least part of the second sub-pixel PIXB. An orthographic projection of the second color resist unit CFB on the base substrate BP is at least partially located at the first direction D1 side of the orthographic projection of the second sub-pixel PIXB on the base substrate BP, and the second color resist unit CFB extends along the second direction D2 to be connected with the second light-shielding portion BMB.

In this way, the first light-shielding portion BMA is located above the first sub-pixel PIXA (the direction away from the base substrate BP) and is offset towards the first direction D1 side, which makes the light exit projection space VA of the first sub-pixel PIXA be oriented towards the second direction D2 or mainly be oriented towards the second direction D2. The second light-shielding portion BMB is located above the second sub-pixel PIXB (the direction away from the base substrate BP) and is offset towards the second direction D2 side, which makes the light exit projection space VB of the second sub-pixel PIXB be oriented towards the first direction D1 or mainly be oriented towards the first direction D1. In this way, the separation of the light exit projection space VA of the first sub-pixel PIXA and the light exit projection space VB of the second sub-pixel PIXB at the first direction D1 side of the display panel and the separation at the second direction D2 side can be achieved.

In an implementation, the boundary EA1 of the light exit projection space VA of the first sub-pixel PIXA may be adjusted by adjusting a distance between an edge of the first light-shielding portion BMA at the second direction D2 side and an edge of the first sub-pixel PIXA at the second direction D2 side. When the distance between the edge of the first light-shielding portion BMA at the second direction D2 side and the edge of the first sub-pixel PIXA at the second direction D2 side decreases, the angle between the boundary EA1 and the second direction D2 also decreases. Similarly, the boundary EB2 of the light exit projection space VB of the second sub-pixel PIXB may be adjusted by adjusting a distance between an edge of the second light-shielding portion BMB at the first direction D1 side and an edge of the second sub-pixel PIXB at the first direction D1 side. When the distance between the edge of the second light-shielding portion BMB at the first direction D1 side and the edge of the second sub-pixel PIXB at the first direction D1 side decreases, the angle between the boundary EB2 and the first direction D1 also decreases.

In an optional solution of the implementation, in at least part of the second light exit units PVSB, the first sub-pixel PIXA partially overlaps with the first light-shielding portion BMA, and a size of a part of the first sub-pixel PIXA overlapping with the first light-shielding portion BMA in the first direction D1 does not exceed half of a size of a first sub-pixel PIXA in the first direction D1. Further, for any one second light exit unit PVSB, the first sub-pixel PIXA partially overlaps with the first light-shielding portion BMA, and the size of the part of the first sub-pixel PIXA overlapping with the first light-shielding portion BMA in the first direction D1 does not exceed half of the size of the first sub-pixel PIXA in the first direction D1.

In an example, an orthographic projection of the edge of the first light-shielding portion BMA at the second direction D2 side on the base substrate BP at least partially overlaps with an orthographic projection of the edge of the first sub-pixel PIXA at the side in the first direction D1 on the base substrate BP.

In an example, an orthographic projection of a geometric center of the first sub-pixel PIXA on the base substrate BP is located on the orthographic projection of the edge of the first light-shielding portion BMA at the second direction D2 side on the base substrate BP. In this example, the first light-shielding portion BMA has a relatively large size, which can better separate the light exit projection space VA of the first sub-pixel PIXA and the light exit projection space VB of the second sub-pixel PIXB at the first direction D1 side of the display panel, thereby achieving a better privacy protection effect at the first direction D1 side.

In an optional solution of the implementation, in at least part of the second light exit units PVSB, the second sub-pixel PIXB partially overlaps with the second light-shielding portion BMB, and a size of a part of the second sub-pixel PIXB overlapping with the second light-shielding portion BMB in the second direction D2 does not exceed half of a size of a second sub-pixel PIXB in the first direction D1. Further, for any one second light exit unit PVSB, the second sub-pixel PIXB partially overlaps with the second light-shielding portion BMB, and the size of the part of the second sub-pixel PIXB overlapping with the second light-shielding portion BMB in the first direction D1 does not exceed half of the size of the second sub-pixel PIXB in the first direction D1.

In an example, an orthographic projection of the edge of the second light-shielding portion BMB at the first direction D1 side on the base substrate BP at least partially overlaps with an orthographic projection of the edge of the second sub-pixel PIXB at the second direction D2 side on the base substrate BP.

In an example, an orthographic projection of a geometric center of the second sub-pixel PIXB on the base substrate BP is located on the orthographic projection of the edge of the second light-shielding portion BMB at the first direction D1 side on the base substrate BP. In this example, the second light-shielding portion BMB has a relatively large size, which can better separate the light exit projection space VA of the first sub-pixel PIXA and the light exit projection space VB of the second sub-pixel PIXB at the second direction D2 side of the display panel, thereby achieving a better privacy protection effect at the second direction D2 side.

In an optional solution of the implementation, the distance between the first color filter layer CFLA and the pixel layer F200 is not smaller than the size of a sub-pixel group PIXS along the first direction D1. In this way, it is possible to prevent the spacing between the first color filter layer CFLA and the driving layer F100 from being too small, better define the light exit projection space VA of the first sub-pixel PIXA and the light exit projection space VB of the second sub-pixel PIXB, prevent an angle between the boundary EA1 and the second direction D2 from being too large, and prevent an angle between the boundary EB2 and the first direction D1 from being too large, and this is more conducive to the separation of the light exit projection space VA of the first sub-pixel PIXA and the light exit projection space VB of the second sub-pixel PIXB.

In an optional solution of the implementation, the viewing-angle definition layer VDL may further include a first black matrix layer BML1 between the pixel layer F200 and the light-transmitting medium layer IJP. The second viewing-angle definition structure VDSB further includes a first bottom light-shielding portion BMAx and a second bottom light-shielding portion BMBx located in the first black matrix layer BML1. The first bottom light-shielding portion BMAx overlaps with the first light-shielding portion BMA, and the second bottom light-shielding portion BMBx overlaps with the second light-shielding portion BMB. For example, an orthographic projection of the first bottom light-shielding portion BMAx on the base substrate BP does not exceed an orthographic projection of the first light-shielding portion BMA on the base substrate BP. An orthographic projection of the second bottom light-shielding portion BMBx on the base substrate BP does not exceed an orthographic projection of the second light-shielding portion BMB on the base substrate BP. In this way, the light leakage risk of the first sub-pixel PIXA at a wide viewing angle at the first direction D1 side can be reduced, and the light leakage risk of the second sub-pixel PIXB at a wide viewing angle at the second direction D2 side can be reduced, thereby improving the privacy protection effect of the display panel in the privacy mode, and improving the display effect of the display panel in the privacy mode.

In an example, the orthographic projection of the first light-shielding portion BMA on the base substrate BP coincides with the orthographic projection of the first bottom light-shielding portion BMAx on the base substrate BP. The orthographic projection of the second light-shielding portion BMB on the base substrate BP coincides with the orthographic projection of the second bottom light-shielding portion BMBx on the base substrate BP. In this way, the mask for preparing the first black matrix layer BML1 may be applied to the preparation process of the first color filter layer CFLA, which can reduce the number of masks required in the preparation process of the display panel, thereby reducing the preparation cost of the display panel. Alternatively, in other examples of the present disclosure, the shape or size of the first light-shielding portion BMA or the orthographic projection position of the first light-shielding portion BMA on the base substrate BP may not be completely consistent with that of the first bottom light-shielding portion BMAx; the shape or size of the second light-shielding portion BMB or the orthographic projection position of the second light-shielding portion BMB on the base substrate BP may not be completely consistent with that of the second bottom light-shielding portion BMBx.

In an implementation of the present disclosure, the viewing-angle definition layer VDL may adopt a scheme of setting multiple layers of black matrix to achieve the definition of the light exit projection space VA of the first sub-pixel PIXA and the light exit projection space VB of the second sub-pixel PIXB.

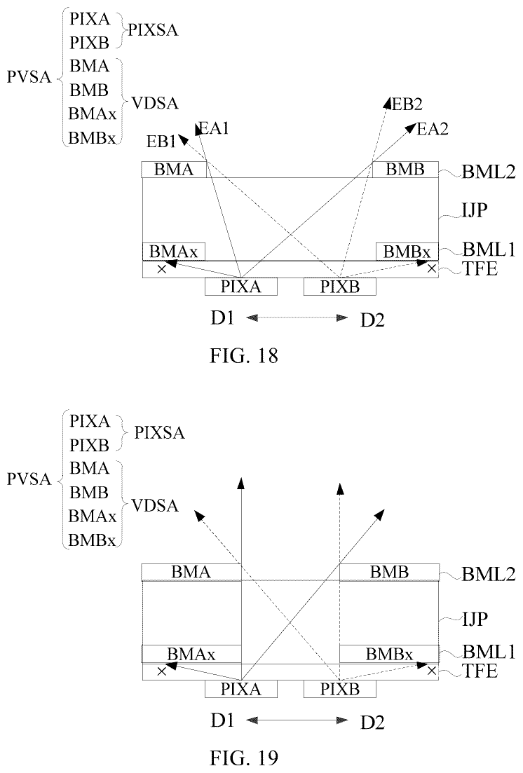

In some implementations of the present disclosure, referring to FIGS. 18 and 19, the viewing-angle definition layer VDL includes a first black matrix layer BML1, a light-transmitting medium layer IJP and a second black matrix layer BML2 which are sequentially stacked at a side of the pixel layer F200 away from the base substrate BP. The viewing-angle definition layer VDL has viewing-angle definition structures VDS corresponding to the sub-pixel groups PIXS one to one; the sub-pixel groups PIXS and the corresponding viewing-angle definition structures VDS form light exit units.

In an implementation, the light exit units include a first light exit unit PVSA. The first light exit unit PVSA includes a first sub-pixel group PIXSA and a first viewing-angle definition structure VDSA corresponding to the first sub-pixel group PIXSA. In the first light exit unit PVSA, the first sub-pixel PIXA is located at the first direction D1 side of the second sub-pixel PIXB. The first viewing-angle definition structure VDSA includes a first light-shielding portion BMA and a first bottom light-shielding portion BMAx corresponding to the first sub-pixel PIXA, and a second light-shielding portion BMB and a second bottom light-shielding portion BMBx corresponding to the second sub-pixel PIXB. The first bottom light-shielding portion BMAx and the second bottom light-shielding portion BMBx are located in the first black matrix layer BML1, and the first light-shielding portion BMA and the second light-shielding portion BMB are located in the second black matrix layer BML2. An orthographic projection of the first light-shielding portion BMA on the base substrate BP is at least partially located at the first direction D1side of an orthographic projection of the first sub-pixel PIXA on the base substrate BP, and the first light-shielding portion BMA exposes at least part of the first sub-pixel PIXA. An orthographic projection of the first bottom light-shielding portion BMAx on the base substrate BP is at least partially located at the first direction D1 side of the orthographic projection of the first sub-pixel PIXA on the base substrate BP, and the first bottom light-shielding portion BMAx exposes at least part of the first sub-pixel PIXA. An orthographic projection of the second light-shielding portion BMB on the base substrate BP is at least partially located at the second direction D2 side of an orthographic projection of the second sub-pixel PIXB on the base substrate BP, and the second light-shielding portion BMB exposes at least part of the second sub-pixel PIXB. An orthographic projection of the second bottom light-shielding portion BMBx on the base substrate BP is at least partially located at the second direction D2 side of the orthographic projection of the second sub-pixel PIXB on the base substrate BP, and the second bottom light-shielding portion BMBx exposes at least part of the second sub-pixel PIXB.

Referring to FIG. 18, in the first light exit unit PVSA, the light emitted by the first sub-pixel PIXA and the second sub-pixel PIXB is emitted from the color resist unit CF and is shielded by the first light-shielding portion BMA, the second light-shielding portion BMB, the first bottom light-shielding portion BMAx, and the second bottom light-shielding portion BMBx. In this example, the first light-shielding portion BMA and the first bottom light-shielding portion BMAx are not located directly above the first sub-pixel PIXA (in the direction away from the base substrate BP), but are offset towards the first direction D1 side. This makes the light exit projection space VA of the first sub-pixel PIXA mainly be oriented towards the second direction D2 side. Correspondingly, the second light-shielding portion BMB and the second bottom light-shielding portion BMBx are not located directly above the second sub-pixel PIXB (in the direction away from the base substrate BP), but are offset towards the second direction D2 side. This makes the light exit projection space VB of the second sub-pixel PIXB mainly be oriented towards the first direction D1 side. Therefore, in front of the display panel, the light exit projection space VA of the first sub-pixel PIXA and the light exit projection space VB of the second sub-pixel PIXB may be at least partially separated. In at least part of the region at the first direction D1 side in front of the display panel, a user can see the second image displayed by the second sub-pixel PIXB, but cannot see the first image displayed by the first sub-pixel PIXA. In at least part of the region at the second direction D2 side in front of the display panel, a user can see the first image displayed by the first sub-pixel PIXA, but cannot see the second image displayed by the second sub-pixel PIXB.

In an implementation, the first black matrix layer BML1 is arranged close to the pixel layer F200, which can reduce the light leakage risk of the first sub-pixel PIXA at a wide viewing angle at the first direction D1 side, and reduce the light leakage risk of the second sub-pixel PIXB at a wide viewing angle at the second direction D2 side, thereby improving the privacy protection effect of the display panel in the privacy mode, and improving the display effect of the display panel in the privacy mode.

In an optional solution of the implementation, in at least part of the first light exit units PVSA, an orthographic projection of the first bottom light-shielding portion BMAx on the base substrate BP does not exceed an orthographic projection of the first light-shielding portion BMA on the base substrate BP, and an orthographic projection of the second bottom light-shielding portion BMBx on the base substrate BP does not exceed an orthographic projection of the second light-shielding portion BMB on the base substrate BP. In the implementation, an angle between the boundary EA1 and the second direction D2 is limited by a distance between an inner edge of the first light-shielding portion BMA (the edge of the first light-shielding portion BMA at a side close to the second sub-pixel PIXB) and an inner edge of the first sub-pixel PIXA (the edge of the first sub-pixel PIXA at a side close to the second sub-pixel PIXB) in the first direction D1, or is limited by a distance between an inner edge of the first bottom light-shielding portion BMAx (the edge of the first bottom light-shielding portion BMAx at a side close to the second sub-pixel PIXB) and the inner edge of the first sub-pixel PIXA in the first direction D1, whichever is smaller. An angle between the boundary EB1 and the second direction D2 is limited by a distance between the inner edge of the first light-shielding portion BMA and the inner edge of the first sub-pixel PIXA in the first direction D1. Therefore, the light exit projection space VA of the first sub-pixel PIXA and the light exit projection space VB of the second sub-pixel PIXB can be adjusted by adjusting the distance between the inner edge of the first light-shielding portion BMA and the inner edge of the first sub-pixel PIXA in the first direction D1, or the distance between the inner edge of the first bottom light-shielding portion BMAx and the inner edge of the first sub-pixel PIXA in the first direction D1, etc.

In an optional solution of the implementation, in at least part of the first light exit units PVSA, the first sub-pixel PIXA partially overlaps with the first light-shielding portion BMA, and a size of a part of the first sub-pixel PIXA overlapping with the first light-shielding portion BMA in the first direction D1 does not exceed half of the size of the first sub-pixel PIXA in the first direction D1.

In an optional solution of the implementation, in at least part of the first light exit units PVSA, the first sub-pixel PIXA partially overlaps with the first bottom light-shielding portion BMAx, and a size of a part of the first sub-pixel PIXA overlapping with the first bottom light-shielding portion BMAx in the first direction D1 does not exceed half of the size of the first sub-pixel PIXA in the first direction D1.

In this way, the viewing-angle definition layer VDL can not only effectively define the orientation of the boundary EA1 and the boundary EB1 to limit the light exit projection space VA of the first sub-pixel PIXA and the light exit projection space VB of the second sub-pixel PIXB, but also prevent the size of the opening between the first light-shielding portion BMA and the second light-shielding portion BMB in the first direction D1 from being too small and prevent the size of the opening between the first bottom light-shielding portion BMAx and the second bottom light-shielding portion BMBx in the first direction D1 from being too small, thereby preventing the first black matrix layer BML1 and the second black matrix layer BML2 from having too low aperture ratio, which would cause the brightness of the first sub-pixel PIXA and the second sub-pixel PIXB to be excessively reduced. Accordingly, the display panel maintains an appropriate aperture ratio.

Further, for any one first light exit unit PVSA, the first sub-pixel PIXA partially overlaps with the first light-shielding portion BMA, and the first sub-pixel PIXA partially overlaps with the first bottom light-shielding portion BMAX. A size of a part of the first sub-pixel PIXA overlapping with the first light-shielding portion BMA in the first direction D1 does not exceed half of the size of the first sub-pixel PIXA in the first direction D1. A size of a part of the first sub-pixel PIXA overlapping with the first bottom light-shielding portion BMAx in the first direction D1 does not exceed half of the size of the first sub-pixel PIXA in the first direction D1.

In an example, referring to FIG. 18, an orthographic projection of the inner edge of the first light-shielding portion BMA on the base substrate BP at least partially overlaps, for example overlaps, with the orthographic projection of the outer edge of the first sub-pixel PIXA (the edge of the first sub-pixel PIXA away from the second sub-pixel PIXB) on the base substrate BP.

In an example, referring to FIG. 18, the orthographic projection of the inner edge of the first bottom light-shielding portion BMAx on the base substrate BP at least partially overlaps, for example overlaps, with the orthographic projection of the outer edge of the first sub-pixel PIXA (the edge of the first sub-pixel PIXA away from the second sub-pixel PIXB) on the base substrate BP.

In an example, referring to FIG. 19, the orthographic projection of the geometric center of the first sub-pixel PIXA on the base substrate BP is located on the orthographic projection of the inner edge of the first light-shielding portion BMA on the base substrate BP. In other words, the first sub-pixel PIXA is divided into a first part located at the first direction D1 side and a second part located at the second direction D2 side, and the boundary between the first part and the second part passes through the geometric center of the first sub-pixel PIXA. The first part of the first sub-pixel PIXA is shielded by the first light-shielding portion BMA, and the second part of the first sub-pixel PIXA is exposed by the first light-shielding portion BMA. In this example, the first light-shielding portion BMA has a relatively large size, which can make the light exit projection space VA of the first sub-pixel PIXA and the light exit projection space VB of the second sub-pixel PIXB better separated at the first direction D1 side of the display panel, and achieve better privacy protection effect at the first direction D1 side.

In an example, referring to FIG. 19, the orthographic projection of the geometric center of the first sub-pixel PIXA on the base substrate BP is located on the orthographic projection of the inner edge of the first bottom light-shielding portion BMAx on the base substrate BP. In other words, the first part of the first sub-pixel PIXA is shielded by the first bottom light-shielding portion BMAx, and the second part of the first sub-pixel PIXA is exposed by the first bottom light-shielding portion BMAx. In this example, the first bottom light-shielding portion BMAx has a relatively large size, which can better separate the light exit projection space VA of the first sub-pixel PIXA and the light exit projection space VB of the second sub-pixel PIXB at the first direction D1 side of the display panel, thereby achieving a better privacy protection effect at the first direction D1 side.

In an optional solution of the implementation, in at least part of the first light exit units PVSA, the second sub-pixel PIXB partially overlaps with the second light-shielding portion BMB, and a size of a part of the second sub-pixel PIXB overlapping with the second light-shielding portion BMB in the first direction D1 does not exceed half of a size of the second sub-pixel PIXB in the first direction D1.

In an optional solution of the implementation, in at least part of the first light exit units PVSA, the second sub-pixel PIXB partially overlaps with the second bottom light-shielding portion BMBx, and a size of a part of the second sub-pixel PIXB overlapping with the second bottom light-shielding portion BMBx in the first direction D1 does not exceed half of the size of the second sub-pixel PIXB in the first direction D1.

In this way, the viewing-angle definition layer VDL can not only effectively define the orientation of the boundary EA2 and the boundary EB2 to define the light exit projection space VA of the first sub-pixel PIXA and the light exit projection space VB of the second sub-pixel PIXB, but also prevent the size of the opening between the first light-shielding portion BMA and the second light-shielding portion BMB in the first direction D1 from being too small and prevent the size of the opening between the first bottom light-shielding portion BMAx and the second bottom light-shielding portion BMBx in the first direction D1 from being too small, thereby preventing the first black matrix layer BML1 and the second black matrix layer BML2 from having too low aperture ratio, which causes the brightness of the first sub-pixel PIXA and the second sub-pixel PIXB to be excessively reduced. Accordingly, the display panel maintains an appropriate aperture ratio.

Further, for any one first light exit unit PVSA, the second sub-pixel PIXB partially overlaps with the second light-shielding portion BMB, and the second sub-pixel PIXB partially overlaps with the second bottom light-shielding portion BMBx. The size of the part of the second sub-pixel PIXB overlapping with the second light-shielding portion BMB in the first direction D1 does not exceed half of the size of the second sub-pixel PIXB in the first direction D1. The size of the part of the second sub-pixel PIXB overlapping with the second bottom light-shielding portion BMBx in the first direction D1 does not exceed half of the size of the second sub-pixel PIXB in the first direction D1.

In an example, referring to FIG. 18, the orthographic projection of the inner edge of the second light-shielding portion BMB on the base substrate BP at least partially overlaps, for example overlaps, with the orthographic projection of the outer edge of the second sub-pixel PIXB (the edge of the second sub-pixel PIXB away from the first sub-pixel PIXA) on the base substrate BP.

In an example, referring to FIG. 18, the orthographic projection of the inner edge of the second bottom light-shielding portion BMBx on the base substrate BP at least partially overlaps, for example overlaps, with the orthographic projection of the outer edge of the second sub-pixel PIXB (the edge of the second sub-pixel PIXB away from the first sub-pixel PIXA) on the base substrate BP.

In an example, referring to FIG. 19, the orthographic projection of the geometric center of the second sub-pixel PIXB on the base substrate BP is located on the orthographic projection of the inner edge of the second light-shielding portion BMB on the base substrate BP. In other words, the second sub-pixel PIXB is divided into a first part located at second direction D2 side and a second part located at the first direction D1 side, and the boundary between the first part and the second part passes through the geometric center of the second sub-pixel PIXB. The first part of the second sub-pixel PIXB is shielded by the second light-shielding portion BMB, and the second part of the second sub-pixel PIXB is exposed by the second light-shielding portion BMB. In this example, the second light-shielding portion BMB has a relatively large size, which can make the light exit projection space VA of the first sub-pixel PIXA and the light exit projection space VB of the second sub-pixel PIXB better separated at the second direction D2 side of the display panel, and achieve better privacy protection effect at the second direction D2 side.

In an example, referring to FIG. 19, the orthographic projection of the geometric center of the second sub-pixel PIXB on the base substrate BP is located on the orthographic projection of the inner edge of the second bottom light-shielding portion BMBx on the base substrate BP. In other words, the first part of the second sub-pixel PIXB is shielded by the second bottom light-shielding portion BMBx, and the second part of the second sub-pixel PIXB is exposed by the second bottom light-shielding portion BMBx. In this example, the second bottom light-shielding portion BMBx has a relatively large size, which can better separate the light exit projection space VA of the first sub-pixel PIXA and the light exit projection space VB of the second sub-pixel PIXB at the second direction D2 side of the display panel, thereby achieving a better privacy protection effect at the second direction D2 side.

In an optional solution of the implementation, the orthographic projection of the first light-shielding portion BMA on the base substrate BP overlaps with the orthographic projection of the first bottom light-shielding portion BMAx on the base substrate BP. The orthographic projection of the second light-shielding portion BMB on the base substrate BP overlaps with the orthographic projection of the second bottom light-shielding portion BMBx on the base substrate BP. In this way, the mask for preparing the first black matrix layer BML1 may be applied to the preparation process of the second black matrix layer BML2, which can reduce the number of masks required in the preparation process of the display panel, thereby reducing the preparation cost of the display panel. Alternatively, in other examples of the present disclosure, the shape or size of the first light-shielding portion BMA or orthographic projection position of the first light-shielding portion BMA on the base substrate BP may not be completely consistent with that of the first bottom light-shielding portion BMAx; the shape or size of the second light-shielding portion BMB or the orthographic projection position of the second light-shielding portion BMB on the base substrate BP may not be completely consistent with that of the second bottom light-shielding portion BMBx.

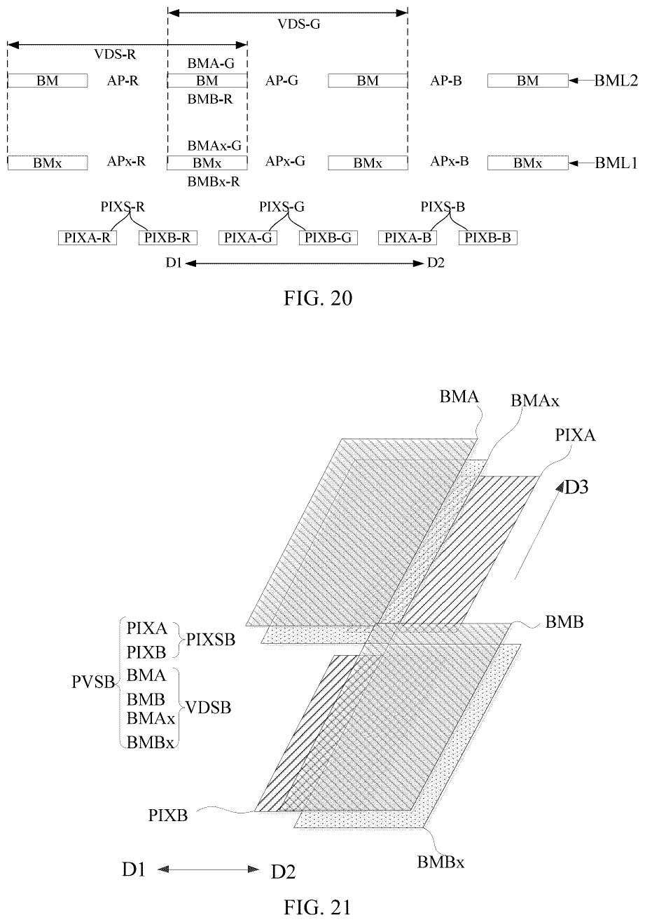

In an optional solution of the implementation, referring to FIG. 20, for two first light exit units PVSA which are adjacent along the first direction D1, a second light-shielding portion BMB of a first light exit unit PVSA located at the first direction D1 side is reused as a first light-shielding portion BMA of a first light exit unit PVSA located at the second direction D2 side, and a second bottom light-shielding portion BMBx of the first light exit unit PVSA located at the first direction D1 side is reused as a first bottom light-shielding portion BMAx of the first light exit unit PVSA located at the second direction D2 side. In other words, along the first direction D1, the first black matrix layer BML1 may include bottom light-shielding portions BMx and first light-transmitting windows (for example, APx-R, APx-G, and APx-B in FIG. 20) located between two adjacent bottom light-shielding portions BMx that are alternately arranged in sequence. The second black matrix layer BML2 may include light-shielding portions BM and second light-transmitting windows (for example, AP-R, AP-G, and AP-B in FIG. 20) located between two adjacent light-shielding portions BM that are alternately arranged in sequence. The pixel layer F200 is provided with a plurality of first sub-pixel groups PIXSA. The first sub-pixel groups PIXSA, the first light-transmitting windows, and the second light-transmitting windows are arranged in one-to-one correspondence. That is, the first sub-pixel groups PIXSA, the first light-transmitting windows, and the second light-transmitting windows, which correspond to each other, overlap with each other. A bottom light-shielding portion BMx at the first direction D1 side of a first light-transmitting window and a bottom light-shielding portion BMx at the second direction D2 side of the first light-transmitting window, and a light-shielding portion BM at the first direction D1 side of a second light-transmitting window and a light-shielding portion BM at the second direction D2 side of the second light-transmitting window form a first viewing-angle definition structure VDSA corresponding to a first sub-pixel group PIXSA corresponding to both the first light-transmitting window and the second light-transmitting window. For a light-shielding portion BM not at an end position, it may be used as a second light-shielding portion BMB of a first viewing-angle definition structure VDSA at the first direction D1 side, and may also be used as a first light-shielding portion BMA of a first viewing-angle definition structure VDSA at the second direction D2 side. For a bottom light-shielding portion BMx at a non-end portion, it may be used as a second bottom light-shielding portion BMBx of a first viewing-angle definition structure VDSA at the first direction D1 side, and may also be used as a first bottom light-shielding portion BMAx of a first viewing-angle definition structure VDSA at the second direction D2 side.

For example, in FIG. 20, along the second direction D2, the display panel includes a plurality of first sub-pixel groups PIXSA arranged in sequence, such as a red sub-pixel group PIXS-R, a green sub-pixel group PIXS-G, and a blue sub-pixel group PIXS-B arranged in sequence. The red sub-pixel group PIXS-R includes a first red sub-pixel PIXA-R located at the first direction D1 side and a second red sub-pixel PIXB-R located at the second direction D2 side. The green sub-pixel group PIXS-G includes a first green sub-pixel PIXA-G located at the first direction D1 side and a second green sub-pixel PIXB-G located at the second direction D2 side. The blue sub-pixel group PIXS-B includes a first blue sub-pixel PIXA-B located at the first direction D1 side and a second blue sub-pixel PIXB-B located at the second direction D2 side. The first black matrix layer BML1 includes bottom light-shielding portions BMx and first light-transmitting windows arranged alternately in sequence along the second direction D2, and the first light-transmitting windows correspond one to one to the sub-pixel groups PIXS. For example, the first light-transmitting windows include a first light-transmitting window APx-R corresponding to the red sub-pixel group PIXS-R, a first light-transmitting window APx-G corresponding to the green sub-pixel group PIXS-G, and a first light-transmitting window APx-B corresponding to the blue sub-pixel group PIXS-B. The second black matrix layer BML2 includes light-shielding portions BM and second light-transmitting windows alternately arranged in sequence along the second direction D2, and the second light-transmitting windows correspond one to one to the sub-pixel group PIXS. For example, the second light-transmitting windows include a second light-transmitting window AP-R corresponding to the red sub-pixel group PIXS-R, a second light-transmitting window AP-G corresponding to the green sub-pixel group PIXS-G, and a second light-transmitting window AP-B corresponding to the blue sub-pixel group PIXS-B.

A bottom light-shielding portion BMx at the first direction D1 side of a first light-transmitting window APx-R, a bottom light-shielding portion BMx at the second direction D2 side of the first light-transmitting window APx-R, a light-shielding portion BM at the first direction D1 side of a second light-transmitting window AP-R and a light-shielding portion BM at the second direction D2 side of the second light-transmitting window AP-R, form a viewing-angle definition structure VDS-R for a red sub-pixel group. The viewing-angle definition structure VDS-R for the red sub-pixel group and the corresponding red sub-pixel group PIXS-R form a first light exit unit PVSA. A bottom light-shielding portion BMx at the first direction Dlside of a first light-transmitting window APx-G, a bottom light-shielding portion BMx at the second direction D2 side of the first light-transmitting window APx-G, a light-shielding portion BM at the first direction D1 side of a second light-transmitting window AP-G and a light-shielding portion BM at the second direction D2 side of the second light-transmitting window AP-G, form a viewing-angle definition structure VDS-G for a green sub-pixel group. The viewing-angle definition structure VDS-G for the green sub-pixel group and the corresponding green sub-pixel group PIXS-G form a first light exit unit PVSA. A bottom light-shielding portion BMx between the first light-transmitting window APx-R and the first light-transmitting window APx-G may be used as the second bottom light-shielding portion BMBx (marked as BMBx-R in FIG. 20) in the viewing-angle definition structure VDS-R for the red sub-pixel group, and may also be used as the first bottom light-shielding portion BMAx (marked as BMAx-G in FIG. 20) in the viewing-angle definition structure VDS-G for the green sub-pixel group. A light-shielding portion BM between the second light-transmitting window AP-R and the second light-transmitting window AP-G may be used as the second light-shielding portion BMB (marked as BMB-R in FIG. 20) in the viewing-angle definition structure VDS-R for the red sub-pixel group, and may also be used as the first light-shielding portion BMA (marked as BMA-G in FIG. 20) in the viewing-angle definition structure VDS-G for the green sub-pixel group.

In an optional solution of the implementation, the distance between the second black matrix layer BML2 and the pixel layer F200 is not smaller than the size of the first sub-pixel group PIXSA along the first direction D1. In this way, it is possible to prevent the spacing between the second black matrix layer BML2 and the pixel layer F200 from being too small, better define the light exit projection space VA of the first sub-pixel PIXA and the light exit projection space VB of the second sub-pixel PIXB, prevent the angle between the boundary EA1 and the second direction D2 from being too large, and prevent the angle between the boundary EB2 and the first direction D1 from being too large, and this is more conducive to the separation of the light exit projection space VA of the first sub-pixel PIXA and the light exit projection space VB of the second sub-pixel PIXB.

In some implementations of the present disclosure, the viewing-angle definition layer VDL includes a first black matrix layer BML1, a light-transmitting medium layer IJP, and a second black matrix layer BML2 stacked in sequence at a side of the pixel layer F200 away from the base substrate BP. The viewing-angle definition layer VDL has viewing-angle definition structures VDS corresponding to the sub-pixel groups PIXS one to one. The sub-pixel groups PIXS and the corresponding viewing-angle definition structures VDS form light exit units.

Referring to FIG. 21, the light exit units include a second light exit unit PVSB. The second light exit unit PVSB may include a second sub-pixel group PIXSB and a second viewing-angle definition structure VDSB corresponding to the second sub-pixel group PIXSB. In the second light exit unit PVSB, the first sub-pixel PIXA is located at a third direction D3 side of the second sub-pixel PIXB. The third direction D3 is perpendicular to the first direction D1. The second viewing-angle definition structure VDSB includes a first light-shielding portion BMA and a first bottom light-shielding portion BMAx corresponding to the first sub-pixel PIXA, and a second light-shielding portion BMB and a second bottom light-shielding portion BMBx corresponding to the second sub-pixel PIXB. The first bottom light-shielding portion BMAx and the second bottom light-shielding portion BMBx are located in the first black matrix layer BML1, and the first light-shielding portion BMA and the second light-shielding portion BMB are located in the second black matrix layer BML2. An orthographic projection of the first light-shielding portion BMA on the base substrate BP is at least partially located at the first direction D1 side of an orthographic projection of the first sub-pixel PIXA on the base substrate BP, and the first light-shielding portion BMA exposes at least part of the first sub-pixel PIXA. An orthographic projection of the first bottom light-shielding portion BMAx on the base substrate BP is at least partially located at the first direction D1 side of the orthographic projection of the first sub-pixel PIXA on the base substrate BP, and the first bottom light-shielding portion BMAx exposes at least part of the first sub-pixel PIXA. An orthographic projection of the second light-shielding portion BMB on the base substrate BP is at least partially located at the second direction D2 side of an orthographic projection of the second sub-pixel PIXB on the base substrate BP, and the second light-shielding portion BMB exposes at least part of the second sub-pixel PIXB. An orthographic projection of the second bottom light-shielding portion BMBx on the base substrate BP is at least partially located at the second direction D2 side of the orthographic projection of the second sub-pixel PIXB on the base substrate BP, and the second bottom light-shielding portion BMBx exposes at least part of the second sub-pixel PIXB.

In this way, the first light-shielding portion BMA and the first bottom light-shielding portion BMAx are located above the first sub-pixel PIXA (the direction away from the base substrate BP) and are shifted to the first direction D1 side, which makes the light exit projection space VA of the first sub-pixel PIXA towards the second direction D2 or mainly towards the second direction D2. The second light-shielding portion BMB and the second bottom light-shielding portion BMBx are located above the second sub-pixel PIXB (the direction away from the base substrate BP) and are shifted to the second direction D2 side, which makes the light exit projection space VB of the second sub-pixel PIXB towards the first direction D1 or mainly towards the first direction D1. This can achieve the separation of the light exit projection space VA of the first sub-pixel PIXA and the light exit projection space VB of the second sub-pixel PIXB at the first direction D1 side of the display panel and at the second direction D2 side of the display panel. The first black matrix layer BML1 is arranged close to the pixel layer F200, which can improve the privacy protection effect of the display panel in the privacy mode, and improve the display effect of the display panel in the privacy mode.

In an optional solution of the implementation, the orthographic projection of the first bottom light-shielding portion BMAx on the base substrate BP does not exceed the orthographic projection of the first light-shielding portion BMA on the base substrate BP, and the orthographic projection of the second bottom light-shielding portion BMBx on the base substrate BP does not exceed the orthographic projection of the second light-shielding portion BMB on the base substrate BP.

In an implementation, the boundary EA1 of the light exit projection space VA of the first sub-pixel PIXA may be adjusted by adjusting the distance between an edge of the first light-shielding portion BMA at the second direction D2 side and an edge of the first sub-pixel PIXA at the second direction D2 side, or by adjusting the distance between an edge of the first bottom light-shielding portion BMAx at a side in the second direction D2 and an edge of the first sub-pixel PIXA at a side in the second direction D2.

In an optional solution of the implementation, in at least part of the second light exit units PVSB, the first sub-pixel PIXA partially overlaps with the first light-shielding portion BMA partially overlap, and a size of a part of the first sub-pixel PIXA overlapping with the first light-shielding portion BMA in the first direction D1 does not exceed half of a size of the first sub-pixel PIXA in the first direction D1.

In an optional solution of the implementation, in at least part of the second light exit units PVSB, the first sub-pixel PIXA partially overlaps with the first bottom light-shielding portion BMAx, and a size of a part of the first sub-pixel PIXA overlapping with the first bottom light-shielding portion BMAx in the first direction D1 does not exceed half of the size of the first sub-pixel PIXA in the first direction D1.

In this way, the first light-shielding portion BMA and the first bottom light-shielding portion BMAx can not only effectively define the boundary EA1, but also avoid excessive shielding on the first sub-pixel PIXA, thereby achieving a balance between the privacy protection effect and the display brightness.

Further, for any one second light exit unit PVSB, the first sub-pixel PIXA partially overlaps with the first light-shielding portion BMA, and the first sub-pixel PIXA partially overlaps with the first bottom light-shielding portion BMAx. The size of a part of the first sub-pixel PIXA overlapping with the first light-shielding portion BMA in the first direction D1 does not exceed half of the size of the first sub-pixel PIXA in the first direction D1. The size of a part of the first sub-pixel PIXA overlapping with the first bottom light-shielding portion BMAx in the first direction D1 does not exceed half of the size of the first sub-pixel PIXA in the first direction D1.

In an example, an orthographic projection of an edge of the first light-shielding portion BMA at the second direction D2 side on the base substrate BP at least partially overlaps, for example, overlaps, with an orthographic projection of an edge of the first sub-pixel PIXA at the first direction D1 side on the base substrate BP.

In an example, an orthographic projection of an edge of the first bottom light-shielding portion BMAx at the second direction D2 side on the base substrate BP at least partially overlaps, for example, overlaps, with the orthographic projection of the edge of the first sub-pixel PIXA at a side in the first direction D1 on the base substrate BP.

In an example, an orthographic projection of a geometric center of the first sub-pixel PIXA on the base substrate BP is located on the orthographic projection of the edge of the first light-shielding portion BMA at the second direction D2 side on the base substrate BP. In other words, the first sub-pixel PIXA is divided into a first part located at the first direction D1 side and a second part located at the second direction D2 side, and a boundary between the first part and the second part passes through the geometric center of the first sub-pixel PIXA. The first part of the first sub-pixel PIXA is shielded by the first light-shielding portion BMA, and the second part of the first sub-pixel PIXA is exposed by the first light-shielding portion BMA. In this example, the first light-shielding portion BMA has a relatively large size, which can improve the directivity of the light exit projection space VA of the first sub-pixel PIXA, so that the light exit projection space VA of the first sub-pixel PIXA and the light exit projection space VB of the second sub-pixel PIXB are better separated at the first direction D1 side of the display panel, and a better privacy protection effect can be achieved at the first direction D1 side.

In an example, the orthographic projection of the geometric center of the first sub-pixel PIXA on the base substrate BP is located on the orthographic projection of the edge of the first bottom light-shielding portion BMAx at the second direction D2 side on the base substrate BP. In other words, the first part of the first sub-pixel PIXA is shielded by the first bottom light-shielding portion BMAx, and the second part of the first sub-pixel PIXA is exposed by the first bottom light-shielding portion BMAx. This is conducive to achieving a better privacy protection effect at the first direction D1 side of the display panel.

In an implementation, the boundary EB2 of the light exit projection space VB of the second sub-pixel PIXB may be adjusted by adjusting the distance between the edge of the second light-shielding portion BMB at the first direction D1 side and the edge of the second sub-pixel PIXB at the first direction D1 side, or by adjusting the distance between the edge of the second bottom light-shielding portion BMBx at the first direction D1 side and the edge of the second sub-pixel PIXB at the first direction D1 side.

In an optional solution of the implementation, in at least part of the second light exit units PVSB, the second sub-pixel PIXB partially overlaps with the second light-shielding portion BMB, and the size of a part of the second sub-pixel PIXB overlapping with the second light-shielding portion BMB in the first direction D1 does not exceed half of the size of the second sub-pixel PIXB in the first direction D1.

In an optional solution of the implementation, in at least part of the second light exit units PVSB, the second sub-pixel PIXB partially overlaps with the second bottom light-shielding portion BMBx, and the size of a part of the second sub-pixel PIXB overlapping with the second bottom light-shielding portion BMBx in the first direction D1 does not exceed half of the size of the second sub-pixel PIXB in the first direction D1.

In this way, the second light-shielding portion BMB and the second bottom light-shielding portion BMBx can not only effectively define the boundary EB2, but also avoid excessive shielding on the second sub-pixel PIXB, thereby achieving a balance between the privacy protection effect and the display brightness.

Further, for any one second light exit unit PVSB, the second sub-pixel PIXB partially overlaps with the second light-shielding portion BMB, and the second sub-pixel PIXB partially overlaps with the second bottom light-shielding portion BMBx. The size of a part of the second sub-pixel PIXB overlapping with the second light-shielding portion BMB in the first direction D1 does not exceed half of the size of the second sub-pixel PIXB in the first direction D1. The size of a part of the second sub-pixel PIXB overlapping with the second bottom light-shielding portion BMBx in the first direction D1 does not exceed half of the size of the second sub-pixel PIXB in the first direction D1.

In an example, the orthographic projection of the edge of the second light-shielding portion BMB at the first direction D1 side on the base substrate BP at least partially overlaps, for example, overlaps, with the orthographic projection of the edge of the second sub-pixel PIXB at the second direction D2 side on the base substrate BP.

In an example, the orthographic projection of the edge of the second bottom light-shielding portion BMBx at the first direction D1 side on the base substrate BP at least partially overlaps, for example, overlaps, with the orthographic projection of the edge of the second sub-pixel PIXB at the second direction D2 side on the base substrate BP.

In an example, the orthographic projection of the geometric center of the second sub-pixel PIXB on the base substrate BP is located on the orthographic projection of the edge of the second light-shielding portion BMB at the first direction D1 side on the base substrate BP. In other words, the second sub-pixel PIXB is divided into a first part located at the second direction D2 side and a second part located at the first direction D1 side, and the boundary between the first part and the second part passes through the geometric center of the second sub-pixel PIXB. The first part of the second sub-pixel PIXB is shielded by the second light-shielding portion BMB, and the second part of the second sub-pixel PIXB is exposed by the second light-shielding portion BMB. In this example, the second light-shielding portion BMB has a relatively large size, which can improve the directivity of the light exit projection space VB of the second sub-pixel PIXB, so that the light exit projection space VA of the first sub-pixel PIXA and the light exit projection space VB of the second sub-pixel PIXB are better separated at the second direction D2 side of the display panel, and a better privacy protection effect is achieved at the second direction D2 side.

In an example, the orthographic projection of the geometric center of the second sub-pixel PIXB on the base substrate BP is located on the orthographic projection of the edge of the second bottom light-shielding portion BMBx at the first direction D1 side on the base substrate BP. In other words, the first part of the second sub-pixel PIXB is shielded by the second bottom light-shielding portion BMBx, and the second part of the second sub-pixel PIXB is exposed by the second bottom light-shielding portion BMBx. In this example, the second bottom light-shielding portion BMBx has a relatively large size, which can improve the directivity of the light exit projection space VB of the second sub-pixel PIXB, so that the light exit projection space VA of the first sub-pixel PIXA and the light exit projection space VB of the second sub-pixel PIXB are better separated at the second direction D2 side of the display panel, and a better privacy protection effect is achieved at the second direction D2 side.

In an optional solution of the implementation, the orthographic projection of the first light-shielding portion BMA on the base substrate BP overlaps with the orthographic projection of the first bottom light-shielding portion BMAx on the base substrate BP. The orthographic projection of the second light-shielding portion BMB on the base substrate BP overlaps with the orthographic projection of the second bottom light-shielding portion BMBx on the base substrate BP. In this way, the mask for preparing the first black matrix layer BML1 may be applied to the preparation process of the second black matrix layer BML2, which can reduce the number of masks required in the preparation process of the display panel, thereby reducing the preparation cost of the display panel. Alternatively, in other examples of the present disclosure, the shape or size of the first light-shielding portion BMA or the orthographic projection position of the first light-shielding portion BMA on the base substrate BP may not be completely consistent with that of the first bottom light-shielding portion BMAx; the shape or size of the second light-shielding portion BMB or orthographic projection position of the second light-shielding portion BMB on the base substrate BP may not be completely consistent with that of the second bottom light-shielding portion BMBx.

In an optional solution of the implementation, the distance between the second black matrix layer BML2 and the pixel layer F200 is not smaller than the size of the sub-pixel group PIXS along the first direction D1. Thus, the solution can prevent the distance between the second black matrix layer BML2 and the pixel layer F200 from being too small, better define the light exit projection space VA of the first sub-pixel PIXA and the light exit projection space VB of the second sub-pixel PIXB, prevent the angle between the boundary EA1 and the second direction D2 from being too large, and prevent the angle between the boundary EB2 and the first direction D1 from being too large, and this is more conducive to the separation of the light exit projection space VA of the first sub-pixel PIXA and the light exit projection space VB of the second sub-pixel PIXB.

The viewing-angle definition layer VDL of the present disclosure may also adopt a scheme of a black matrix+color film which are staggered to define the light exit projection space VA of the first sub-pixel PIXA of a sub-pixel group PIXS and the light exit projection space VB of the second sub-pixel PIXB.

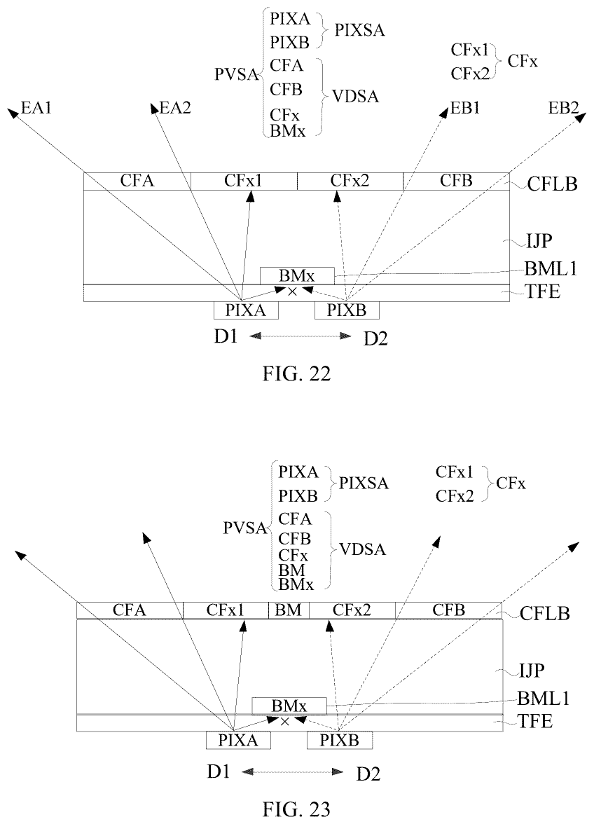

In some implementations of the present disclosure, referring to FIG. 22, the viewing-angle definition layer VDL includes a first black matrix layer BML1, a light-transmitting medium layer IJP, and a second color filter layer CFLB stacked sequentially at a side of the pixel layer F200 away from the base substrate BP. The viewing-angle definition layer VDL includes viewing-angle definition structures VDS corresponding to the sub-pixel groups PIXS. The sub-pixel groups PIXS and the corresponding viewing-angle definition structures VDS form light exit units.

In the implementation, the light exit units include a first light exit unit PVSA. The first light exit unit PVSA includes a first sub-pixel group PIXSA and a first viewing-angle definition structure VDSA corresponding to the first sub-pixel group PIXSA. In the first light exit unit PVSA, the first sub-pixel PIXA is located at the first direction D1 side of the second sub-pixel PIXB. The first viewing-angle definition structure VDSA includes a first color resist unit CFA corresponding to the first sub-pixel PIXA, a second color resist unit CFB corresponding to the second sub-pixel PIXB, and an auxiliary color resist unit CFx between the first color resist unit CFA and the second color resist unit CFB and a bottom light-shielding portion BMx located in the first black matrix layer BML1. The first color resist unit CFA, the second color resist unit CFB and the auxiliary color resist unit CFx are located in the second color filter layer CFLB. The colors of the first color resist unit CFA and the second color resist unit CFB are the same as the light-emitting color of the sub-pixel group PIXS, and the color of the auxiliary color resist unit CFx is different from the light-emitting color of the sub-pixel group PIXS.

An orthographic projection of the first color resist unit CFA on the base substrate BP is located at the first direction D1 side of an orthographic projection of the first sub-pixel PIXA on the base substrate BP. An orthographic projection of the second color resist unit CFB on the base substrate BP is located at the second direction D2 side of an orthographic projection of the second sub-pixel PIXB on the base substrate BP. An orthographic projection of the bottom light-shielding portion BMx on the base substrate BP at least covers a gap between the first sub-pixel PIXA and the second sub-pixel PIXB. A light path between the second sub-pixel PIXB and the first color resist unit CFA is blocked by the bottom light-shielding portion BMx, and a light path between the first sub-pixel PIXA and the second color resist unit CFB is blocked by the bottom light-shielding portion BMX.

In the implementation, referring to FIG. 22, a part of the light emitted by the first sub-pixel PIXA that is irradiated towards the direction of the second color resist unit CFB is blocked by the bottom light-shielding portion BMx. This prevents the light of the first sub-pixel PIXA from being emitted from the second color resist unit CFB. A part of light of the first sub-pixel PIXA that is irradiated towards the direction of the auxiliary color resist unit CFx is absorbed by the auxiliary color resist unit CFx and emitted. Therefore, the light emitted by the first sub-pixel PIXA can only be emitted through the first color resist unit CFA. Thus, the light exit projection space VA of the first sub-pixel PIXA is oriented towards the first direction D1 side of the display panel. Similarly, a part of the light emitted by the second sub-pixel PIXB that is irradiated towards the direction of the first color resist unit CFA is blocked by the bottom light-shielding portion BMx. This prevents the light of the second sub-pixel PIXB from being emitted from the first color resist unit CFA. A part of light of the second sub-pixel PIXB that is irradiated towards the direction of the auxiliary color resist unit CFx is absorbed by the auxiliary color resist unit CFx and emitted. Therefore, the light emitted by the second sub-pixel PIXB can only be emitted through the second color resist unit CFB. Thus, the light exit projection space VB of the second sub-pixel PIXB is towards the second direction D2 side of the display panel. In the implementation, by making the first color resist unit CFA located at the first direction D1 side of the first sub-pixel PIXA and making the second color resist unit CFB located at the second direction D2 side of the second sub-pixel PIXB, the light exit projection space VA of the first sub-pixel PIXA of the first sub-pixel group PIXSA and the light exit projection space VB of the second sub-pixel PIXB can be completely separated, which can maximize the privacy protection effect.

In an optional solution of the implementation, in at least part of the first light exit units PVSA, the bottom light-shielding portion BMx partially overlaps with the first sub-pixel PIXA, and the size of a part of the first sub-pixel PIXA overlapping with the bottom light-shielding portion BMx in the first direction D1 does not exceed half of the size of the first sub-pixel PIXA in the first direction D1. In this way, it is possible to avoid the width of the bottom light-shielding portion BMx (the size in the first direction D1) being too large to excessively shield the first sub-pixel PIXA, thereby avoiding an excessive reduction in the display brightness of the first sub-pixel PIXA because the light path between the first sub-pixel PIXA and the first color resist unit CFA is excessively blocked. Also, it is possible to prevent the width of the bottom light-shielding portion BMx from being too small to fully block the light path between the first sub-pixel PIXA and the second color resist unit CFB.

In an optional solution of the implementation, in at least part of the first light exit units PVSA, the second sub-pixel PIXB partially overlaps with the bottom light-shielding portion BMx, and the size of a part of the second sub-pixel PIXB overlapping with the bottom light-shielding portion BMx in the first direction D1 does not exceed half of the size of the second sub-pixel PIXB in the first direction D1. In this way, it is possible to prevent the width of the bottom light-shielding portion BMx (the size in the first direction D1) from being too large, which would otherwise excessively shield the second sub-pixel PIXB. Accordingly, this can avoid excessive reduction in the display brightness of the second sub-pixel PIXB because the light path between the second sub-pixel PIXB and the second color resist unit CFB is excessively blocked. Also, it is possible to prevent the width of the bottom light-shielding portion BMx from being too small to fully block the light path between the second sub-pixel PIXB and the first color resist unit CFA.

Further, for any one first light exit unit PVSA, the bottom light-shielding portion BMx partially overlaps with the first sub-pixel PIXA, and the size of a part of the first sub-pixel PIXA overlapping with the bottom light-shielding portion BMx in the first direction D1 does not exceed half of the size of the first sub-pixel PIXA in the first direction D1. For any one first light exit unit PVSA, the second sub-pixel PIXB partially overlaps with the bottom light-shielding portion BMx, and the size of a part of the second sub-pixel PIXB overlapping with the bottom light-shielding portion BMx in the first direction D1 does not exceed half of the size of the second sub-pixel PIXB in the first direction D1.

In an example, in at least part of the first light exit units PVSA, an orthographic projection of an edge of the first sub-pixel PIXA at the second direction D2 side on the base substrate BP at least partially overlaps, for example, completely overlaps, with an orthographic projection of an edge of the bottom light-shielding portion BMx at the first direction D1 side on the base substrate BP.

In an example, in at least part of the first light exit units PVSA, an orthographic projection of an edge of the second sub-pixel PIXB at the first direction D1 side on the base substrate BP at least partially overlaps, for example, completely overlaps, with an orthographic projection of an edge of the bottom light-shielding portion BMx at the second direction D2 side on the base substrate BP.

In an optional solution of the implementation, referring to FIG. 22, in at least part of the first light exit units PVSA, the number of the auxiliary color resist units CFx is two, and the auxiliary color resist units CFx include a first auxiliary color resist unit CFx1 and a second auxiliary color resist unit CFx2, and the first auxiliary color resist unit CFx1 is located at the first direction D1 side of the second auxiliary color resist unit CFx2. The color of the first auxiliary color resist unit CFx1 may be different from the color of the second auxiliary color resist unit CFx2.

In an optional solution of the implementation, referring to FIG. 23, in at least part of the first light exit units PVSA, the auxiliary color resist units CFx include a first auxiliary color resist unit CFx1 and a second auxiliary color resist unit CFx2, and the first auxiliary color resist unit CFx1 is located at the first direction D1 side of the second auxiliary color resist unit CFx2. The first light exit unit PVSA further includes a light-shielding portion BM located between the first auxiliary color resist unit CFx1 and the second auxiliary color resist unit CFx2 and disposed in the second color filter layer CFLB. In this way, the light-shielding portion BM may accurately define the edges of the first auxiliary color resist unit CFx1 and the second auxiliary color resist unit CFx2. In an example, an orthographic projection of the light-shielding portion BM on the base substrate BP is located within an orthographic projection range of the bottom light-shielding portion BMx on the base substrate BP. That is, the size of the light-shielding portion BM along the first direction D1 may be smaller than the size of the bottom light-shielding portion BMx. In this way, the first auxiliary color resist unit CFx1 and the second auxiliary color resist unit CFx2 may have a relatively large width. Furthermore, the orthographic projection of the light-shielding portion BM on the base substrate BP overlaps with the orthographic projection of the bottom light-shielding portion BMx on the base substrate BP.

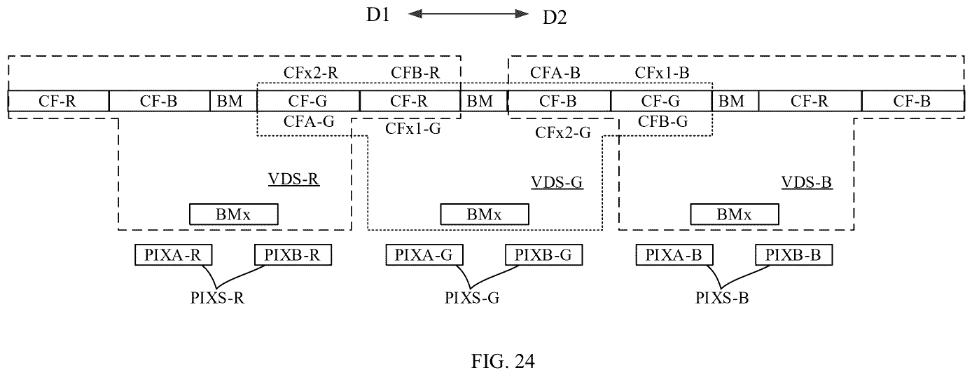

In an optional solution of the implementation, referring to FIG. 24, for two first light exit units PVSA which are adjacent along the first direction D1, a second auxiliary color resist unit CFx2 of a first light exit unit PVSA located at a first direction D1 side is reused as a first color resist unit CFA of a first light exit unit PVSA located at the second direction D2 side, and a first auxiliary color resist unit CFx1 of a first light exit unit PVSA located at the second direction D2 side is reused as a second color resist unit CFB of a first light exit unit PVSA located at the first direction D1 side.

For example, referring to FIG. 24, along the second direction D2, the display panel includes a plurality of first sub-pixel groups PIXSA arranged in sequence, such as a red sub-pixel group PIXS-R, a green sub-pixel group PIXS-G, and a blue sub-pixel group PIXS-B arranged in sequence. The red sub-pixel group PIXS-R includes a first red sub-pixel PIXA-R located at the first direction D1 side and a second red sub-pixel PIXB-R located at the second direction D2 side. The green sub-pixel group PIXS-G includes a first green sub-pixel PIXA-G located at first direction D1 side and a second green sub-pixel PIXB-G located at the second direction D2 side. The blue sub-pixel group PIXS-B includes a first blue sub-pixel PIXA-B located at the first direction D1 side and a second blue sub-pixel PIXB-B located at the second direction D2 side. The first black matrix layer BML1 includes bottom light-shielding portions BMx and light-transmitting windows arranged alternately in sequence along the second direction D2, and the bottom light-shielding portions BMx are arranged in one-to-one correspondence with the first sub-pixel groups PIXSA. The second color filter layer CFLB includes a plurality of color resist units CF sequentially arranged along the second direction D2, and the color of any one color resist unit CF is different from the color of a first sub-pixel group PIXSA overlapping with the color resist unit CF, and is the same as the color of an adjacent first sub-pixel group PIXSA. For example, the second color filter layer CFLB includes a red color resist unit CF-R, a blue color resist unit CF-B, and a green color resist unit CF-G sequentially and periodically arranged along the second direction D2. A color resist unit overlapping with the first red sub-pixel PIXA-R is a blue color resist unit CF-B. A color resist unit overlapping with the second red sub-pixel PIXB-R is a green color resist unit CF-G. A color resist unit overlapping with the first green sub-pixel PIXA-G is a red color resist unit CF-R. A color resist unit overlapping with the second green sub-pixel PIXB-G is a blue color resist unit CF-B. A color resist unit overlapping with the first blue sub-pixel PIXA-B is a green color resist unit CF-G. A color resist unit overlapping with the second blue sub-pixel PIXB-B is a red color resist unit CF-R. Referring to FIG. 24, the second color resist unit CFB (labeled as CFB-R in FIG. 24) in the viewing-angle definition structure VDS-R for the red sub-pixel group may be used as the first auxiliary color resist unit CFx1 (labeled as CFx1-G in FIG. 24) in the viewing-angle definition structure VDS-G for the green sub-pixel group. The second auxiliary color resist unit CFx2 (labeled as CFx2-R in FIG. 24) in the viewing-angle definition structure VDS-R for the red sub-pixel group may be used as the first color resist unit CFA (labeled as CFA-G in FIG. 24) in the viewing-angle definition structure VDS-G for the green sub-pixel group. The second auxiliary color resist unit CFx2 (marked as CFx2-G in FIG. 24) in the viewing-angle definition structure VDS-G for the green sub-pixel group may be used as the first color resist unit CFA (marked as CFA-B in FIG. 24) in the viewing-angle definition structure VDS-B for the blue sub-pixel group. The second color resist unit CFB (marked as CFB-G in FIG. 24) in the viewing-angle definition structure VDS-G for the green sub-pixel group may be used as the first auxiliary color resist unit CFx1 (marked as CFx1-B in FIG. 24) in the viewing-angle definition structure VDS-B for the blue sub-pixel group.

In an optional solution of the implementation, referring to FIG. 23, in at least part of the first light exit units PVSA, an orthographic projection of the first auxiliary color resist unit CFx1 on the base substrate BP covers the first sub-pixel PIXA. An orthographic projection of the second auxiliary color resist unit CFx2 on the base substrate BP covers the second sub-pixel PIXB. In this way, it can be ensured that the first auxiliary color resist unit CFx1 and the second auxiliary color resist unit CFx2 have a relatively large area. In the implementation, although the first auxiliary color resist unit CFx1 is not used to emit the light emitted by the covered sub-pixel group PIXS, it may be used to emit the light emitted by an adjacent sub-pixel group PIXS. Therefore, the first auxiliary color resist unit CFx1 has a relatively large area to ensure that the display panel has a relatively large display brightness. Similarly, the second auxiliary color resist unit CFx2 has a relatively large area to ensure that the display panel has relatively large display brightness.

In an optional solution of the implementation, the distance between the second color filter layer CFLB and the pixel layer F200 is not smaller than the size of a sub-pixel group PIXS along the first direction D1. In this way, the orientations of the light exit projection space VA of the first sub-pixel PIXA and the light exit projection space VB of the second sub-pixel PIXB can be better defined.

In some implementations of the present disclosure, the viewing-angle definition layer VDL includes a first black matrix layer BML1, a light-transmitting medium layer IJP, and a second color filter layer CFLB stacked in sequence at a side of the pixel layer F200 away from the base substrate BP. The viewing-angle definition layer VDL includes viewing-angle definition structures VDS corresponding to the sub-pixel groups PIXS one to one. The sub-pixel groups PIXS and corresponding viewing-angle definition structures VDS form light exit units.

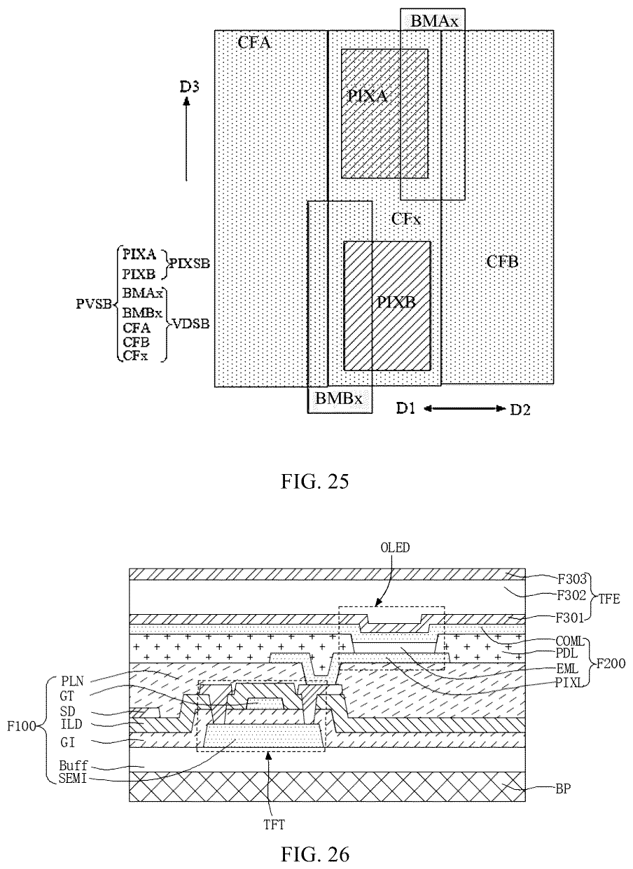

The light exit unit includes a second light exit unit PVSB. Referring to FIG. 25, the second light exit unit PVSB includes a second sub-pixel group PIXSB and a second viewing-angle definition structure VDSB corresponding to the second sub-pixel group PIXSB. In the second light exit unit PVSB, a first sub-pixel PIXA is located at a third direction D3 side of a second sub-pixel PIXB. The third direction D3 is perpendicular to the first direction D1. For the second light exit unit PVSB, the second viewing-angle definition structure VDSB includes a first color resist unit CFA and a first bottom light-shielding portion BMAx corresponding to the first sub-pixel PIXA, a second color resist unit CFB and a second bottom light-shielding portion BMBx corresponding to the second sub-pixel PIXB, and an auxiliary color resist unit CFx between the first color resist unit CFA and the second color resist unit CFB. The first color resist unit CFA, the second color resist unit CFB and the auxiliary color resist unit CFx are located in the second color film layer CFLB. The colors of the first color resist unit CFA and the second color resist unit CFB are the same as the light-emitting color of the sub-pixel group PIXS, and the color of the auxiliary color resist unit CFx is different from the light-emitting color of the sub-pixel group PIXS. The first bottom light-shielding portion BMAx and the second bottom light-shielding portion BMBx are located in the first black matrix layer BML1. An orthographic projection of the first color resist unit CFA on the base substrate BP is located at the first direction D1 side of an orthographic projection of the first sub-pixel PIXA on the base substrate BP. An orthographic projection of the second color resist unit CFB on the base substrate BP is located at the second direction D2 side of an orthographic projection of the second sub-pixel PIXB on the base substrate BP. An orthographic projection of the first bottom light-shielding portion BMAx on the base substrate BP is at least partially located on the second direction D2 side of the orthographic projection of the first sub-pixel PIXA on the base substrate BP. An orthographic projection of the second bottom light-shielding portion BMBx on the base substrate BP is at least partially located at the first direction D1 side of the orthographic projection of the second sub-pixel PIXB on the base substrate BP. A light path between the second sub-pixel PIXB and the first color resist unit CFA is blocked by the second bottom light-shielding portion BMBx, and a light path between the first sub-pixel PIXA and the second color resist unit CFB is blocked by the first bottom light-shielding portion BMAX.

In the implementation, referring to FIG. 25, a part of the light emitted by the first sub-pixel PIXA that is irradiated towards the direction of the second color resist unit CFB is blocked by the first bottom light-shielding portion BMAX. This prevents the light of the first sub-pixel PIXA from being emitted from the second color resist unit CFB. The part of light of the first sub-pixel PIXA that is irradiated towards the direction of the auxiliary color resist unit CFx is absorbed by the auxiliary color resist unit CFx and emitted. Therefore, the light emitted by the first sub-pixel PIXA can only be emitted through the first color resist unit CFA. Thus, the light exit projection space VA of the first sub-pixel PIXA is towards the first direction D1 side of the display panel. Similarly, a part of the light emitted by the second sub-pixel PIXB that is irradiated towards the direction of the first color resist unit CFA is shielded by the second bottom light-shielding portion BMBx. This prevents the light of the second sub-pixel PIXB from being emitted from the first color resist unit CFA. The part of light of the second sub-pixel PIXB that is irradiated towards the auxiliary color resist unit CFx is absorbed by the auxiliary color resist unit CFx and emitted. Therefore, the light emitted by the second sub-pixel PIXB can only be emitted through the second color resist unit CFB. As a result, the light exit projection space VB of the second sub-pixel PIXB is towards the second direction D2 side of the display panel. In the implementation, by making the first color resist unit CFA be located at the first direction D1 side of the first sub-pixel PIXA and making the second color resist unit CFB be located at the second direction D2 side of the second sub-pixel PIXB, the light exit projection space VA of the first sub-pixel PIXA of the first sub-pixel group PIXSA and the light exit projection space VB of the second sub-pixel PIXB can be completely separated, which can maximize the privacy protection effect.

In an optional solution of the implementation, in at least part of the second light exit units PVSB, the first bottom light-shielding portion BMAx partially overlaps with the first sub-pixel PIXA, and the size of a part of the first sub-pixel PIXA overlapping with the first bottom light-shielding portion BMAx in the first direction D1 does not exceed half of the size of the first sub-pixel PIXA in the first direction D1. In this way, it is possible to prevent the width of the first bottom light-shielding portion BMAx (the size in the first direction D1) from being too large, which would otherwise excessively shield the first sub-pixel PIXA. Accordingly, this can avoid excessive reduction in the display brightness of the first sub-pixel PIXA because the light path between the first sub-pixel PIXA and the first color resist unit CFA is excessively blocked. Also, it is possible to prevent the width of the first bottom light-shielding portion BMAx from being too small to fully block the light path between the first sub-pixel PIXA and the second color resist unit CFB.

In an optional solution of the implementation, in at least part of the second light exit units PVSB, the second sub-pixel PIXB partially overlaps with the second bottom light-shielding portion BMBx, and the size of a part of the second sub-pixel PIXB overlapping with the second bottom light-shielding portion BMBx in the first direction D1 does not exceed half of the size of the second sub-pixel PIXB in the first direction D1. In this way, it is possible to prevent the width of the second bottom light-shielding portion BMBx (the size in the first direction D1) from being too large, which would otherwise excessively shield the second sub-pixel PIXB. Accordingly, this can avoid excessive reduction in the display brightness of the second sub-pixel PIXB because the light path between the second sub-pixel PIXB and the second color resist unit CFB is excessively blocked. Also, it is possible to prevent the width of the second bottom light-shielding portion BMBx from being too small to fully block the light path between the second sub-pixel PIXB and the first color resist unit CFA.

In an optional solution of the implementation, the distance between the second color filter layer CFLB and the pixel layer F200 is not smaller than the size of the sub-pixel group PIXS along the first direction D1. In this way, the orientations of the light exit projection space VA of the first sub-pixel PIXA and the light exit projection space VB of the second sub-pixel PIXB can be better defined.

In the above-mentioned implementations of the present disclosure, the structures, principles and purposes of the viewing-angle definition layer VDL are introduced by taking three different schemes as examples, namely, the scheme of black matrix +color film, the scheme of multiple layers of black matrix and the scheme of black matrix +color film which are staggered. It can be understood that in order to at least partially separate the light exit projection space VA of the first sub-pixel PIXA and the light exit projection space VB of the second sub-pixel PIXB, the viewing-angle definition layer VDL may also adopt other schemes and corresponding structures, which will not be described in detail in the present disclosure.

In the above-mentioned implementations of the present disclosure, the implementations and principles of the first viewing-angle definition structure VDSA corresponding to the first sub-pixel group PIXSA and the implementations and principles of the second viewing-angle definition structure VDSB corresponding to the second sub-pixel group PIXSB are also introduced as examples. It can be understood that the first viewing-angle definition structure VDSA corresponding to the first sub-pixel group PIXSA can also adopt other structures to achieve at least partial separation of the light exit projection space VA of the first sub-pixel PIXA and the light exit projection space VB of the second sub-pixel PIXB, and the second viewing-angle definition structure VDSB corresponding to the second sub-pixel group PIXSB can also adopt other structures to achieve at least partial separation of the light exit projection space VA of the first sub-pixel PIXA and the light exit projection space VB of the second sub-pixel PIXB. It can be understood that when there are other types of sub-pixel groups PIXS on the display panel, corresponding viewing-angle definition structures can also be set based on the principles of the implementations of the present disclosure.

When preparing the display panel provided in the implementations of the present disclosure, the display backplane may be prepared first, and then the viewing-angle definition layer may be prepared on a light exit side of the display backplane. It is understandable that when there is a functional film layer between the display backplane and the viewing-angle definition layer, the functional film layer may be prepared first at the light exit side of the display backplane, and then the viewing-angle definition layer may be prepared at the light exit side of the functional film layer.

For example, FIG. 26 to FIG. 29 illustrate the preparation procedure of the display panel in an implementation of the present disclosure. The display panel includes a display backplane, a touch function layer TSL (a functional film layer) and a viewing-angle definition layer VDL which are stacked in sequence, and the viewing-angle definition layer VDL includes a light-transmitting medium layer IJP and a first color filter layer CFLA stacked in sequence.

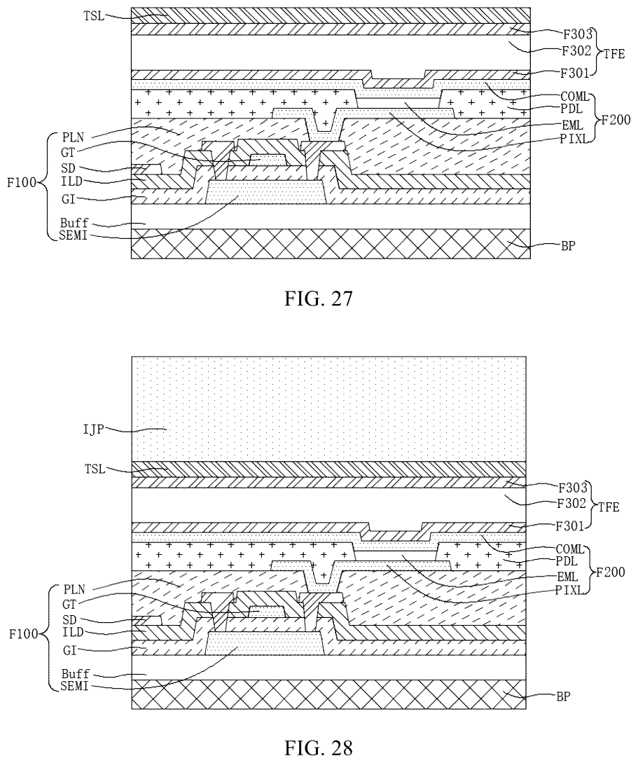

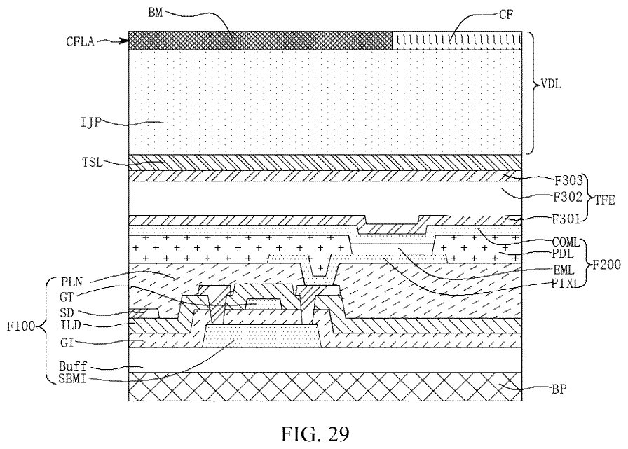

Referring to FIG. 26, the display backplane may be prepared first. The display backplane may include a base substrate BP, a driving layer F100, a pixel layer F200, and an encapsulation layer TFE stacked in sequence. Referring to FIG. 27, a touch function layer TSL is then prepared at the light exit side of the display backplane. Specifically, the touch function layer TSL is prepared at a side of the encapsulation layer TFE away from the base substrate BP. Optionally, the touch function layer TSL may include a buffer layer (which may be omitted in other examples), a first metal layer, a touch medium layer, a second metal layer, and an organic protective layer (which may be omitted in other examples) stacked in sequence at a side of the encapsulation layer TFE away from the base substrate BP. It is understood that when the display panel PNL is not provided with the touch function layer TSL, the step of preparing the touch function layer TSL may be omitted. Referring to FIG. 28, a light-transmitting medium layer IJP is prepared at a side of the touch function layer TSL away from the base substrate BP. A printing technology may be used to prepare the light-transmitting medium layer IJP of a desired thickness. Referring to FIG. 29, a first color filter layer CFLA is prepared at a side of the light-transmitting medium layer IJP away from the base substrate BP. The first color filter layer CFLA includes a light-shielding portion BM and a color resist unit CF.

In the above-mentioned example of the method for preparing the display panel, the display panel PNL includes the touch function layer TSL and the viewing-angle definition layer VDL includes the light-transmitting medium layer IJP and the first color filter layer CFLA which are stacked. It can be understood that when the display panel PNL does not include the touch function layer TSL, or the structure of the viewing-angle definition layer VDL is other types of structures, the method for preparing the display panel PNL can be adaptively changed.

It should be noted that, although the steps of the driving method in the present disclosure are described in a specific order in the drawings, this does not require or imply that the steps must be performed in this specific order, or that all the steps shown must be performed to achieve the desired result(s). Additionally or alternatively, some steps may be omitted, multiple steps may be combined into one step, and/or one step may be decomposed into multiple steps, etc.

Those skilled in the art will readily appreciate other implementations of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be illustrative only, and the true scope and spirit of the present disclosure are indicated by the appended claims.

1. A display panel, comprising a base substrate, a driving layer, a pixel layer and a viewing-angle definition layer stacked sequentially, wherein the pixel layer comprises sub-pixel groups arranged in an array, and any one of the sub-pixel groups comprises a first sub-pixel and a second sub-pixel which are adjacent and have a same color;
wherein the viewing-angle definition layer is capable of making a light exit projection space of the first sub-pixel at most partially overlap with a light exit projection space of the second sub-pixel.

2. The display panel according to claim 1, wherein the viewing-angle definition layer comprises a light-transmitting medium layer and a first color filter layer which are sequentially stacked at a side of the pixel layer away from the base substrate, the first color filter layer comprises viewing-angle definition structures corresponding to the sub-pixel groups one to one, and the sub-pixel groups and corresponding viewing-angle definition structures constitute light exit units;
wherein the light exit units comprises a first light exit unit, and in the first light exit unit, the first sub-pixel is located at a first-direction side of the second sub-pixel, a viewing-angle definition structure of the first light exit unit comprises a first light-shielding portion corresponding to the first sub-pixel, a second light-shielding portion corresponding to the second sub-pixel and a color resist unit between the first light-shielding portion and the second light-shielding portion, and a color of the color resist unit is the same as a light-emitting color of a sub-pixel group of the first light exit unit, wherein the first-direction side is a side in a first direction;
wherein an orthographic projection of the first light-shielding portion on the base substrate is at least partially located at the first-direction side of an orthographic projection of the first sub-pixel on the base substrate, and the first light-shielding portion exposes at least part of the first sub-pixel;
wherein an orthographic projection of the second light-shielding portion on the base substrate is at least partially located at a second-direction side of an orthographic projection of the second sub-pixel on the base substrate, and the second light-shielding portion exposes at least part of the second sub-pixel, the second-direction side is a side in a second direction, and the first direction is opposite to the second direction.

3. The display panel according to claim 2, wherein for two first light exit units which are adjacent along the first direction, a second light-shielding portion of a first light exit unit in the two light exit units located at the first-direction side is reused as a first light-shielding portion of a first light exit unit in the two light exit units located at the second-direction side.

4. The display panel according to claim 1, wherein the viewing-angle definition layer comprises a light-transmitting medium layer and a first color filter layer which are sequentially stacked at a side of the pixel layer away from the base substrate, the first color filter layer comprises viewing-angle definition structures corresponding to the sub-pixel groups one to one, and the sub-pixel groups and corresponding viewing-angle definition structures constitute light exit units;
wherein the light exit units comprise a second light exit unit, and in the second light exit unit, the first sub-pixel is located at a third-direction side of the second sub-pixel, a viewing-angle definition structure of the second light exit unit comprises a first light-shielding portion and a first color resist unit corresponding to the first sub-pixel, and a second light-shielding portion and a second color resist unit corresponding to the second sub-pixel, and colors of the first color resist unit and the second color resist unit are the same as a light-emitting color of a sub-pixel group of the second light exit unit, wherein the third-direction side is a side in a third direction;
wherein an orthographic projection of the first light-shielding portion on the base substrate is at least partially located at a first-direction side of an orthographic projection of the first sub-pixel on the base substrate, and the first light-shielding portion exposes at least part of the first sub-pixel, wherein first-direction side is a side in a first direction;
wherein an orthographic projection of the first color resist unit on the base substrate is at least partially located at a second-direction side of the orthographic projection of the first sub-pixel on the base substrate, and the first color resist unit extends along the first direction to be connected with the first light-shielding portion, wherein the second-direction side is a side in a second direction;
wherein an orthographic projection of the second light-shielding portion on the base substrate is at least partially located at the second-direction side of an orthographic projection of the second sub-pixel on the base substrate, and the second light-shielding portion exposes at least part of the second sub-pixel;
wherein an orthographic projection of the second color resist unit on the base substrate is at least partially located at the first-direction side of the orthographic projection of the second sub-pixel on the base substrate, and the second color resist unit extends along the second direction to be connected with the second light-shielding portion, and the first direction is opposite to the second direction and is perpendicular to the third direction.

5. The display panel according to claim 2, wherein in at least part of the light exit units, the first sub-pixel partially overlaps with the first light-shielding portion, and a size of a part of the first sub-pixel overlapping with the first light-shielding portion in the first direction does not exceed half of a size of the first sub-pixel in the first direction;
and/or, wherein in at least part of the light exit units, a second sub-pixel partially overlaps with a second light-shielding portion, a size of a part of the second sub-pixel overlapping with the second light-shielding portion in the first direction does not exceed half of a size of the second sub-pixel in the first direction;
or, wherein the viewing-angle definition layer further comprises a first black matrix layer between the pixel layer and the light-transmitting medium layer;
wherein the viewing-angle definition structure of the first light exit unit further comprises a first bottom light-shielding portion and a second bottom light-shielding portion located in the first black matrix layer, an orthographic projection of the first bottom light-shielding portion on the base substrate does not exceed the orthographic projection of the first light-shielding portion on the base substrate, and an orthographic projection of the second bottom light-shielding portion on the base substrate does not exceed the orthographic projection of the second light-shielding portion on the base substrate.

6-7. (canceled)

8. The display panel according to claim 1, wherein the viewing-angle definition layer comprises a first black matrix layer, a light-transmitting medium layer and a second black matrix layer which are sequentially stacked at a side of the pixel layer away from the base substrate, the viewing-angle definition layer has viewing-angle definition structures corresponding to the sub-pixel groups one to one, and the sub-pixel groups and corresponding viewing-angle definition structures form light exit units;
wherein the light exit units comprise a first light exit unit, and in the first light exit unit, the first sub-pixel is located at a first-direction side of the second sub-pixel, the viewing-angle definition structure of the first light exit unit comprises a first light-shielding portion and a first bottom light-shielding portion corresponding to the first sub-pixel, and a second light-shielding portion and a second bottom light-shielding portion corresponding to the second sub-pixel, wherein the first-direction side is a side in a first direction;
wherein the first bottom light-shielding portion and the second bottom light-shielding portion are located in the first black matrix layer, and the first light-shielding portion and the second light-shielding portion are located in the second black matrix layer;
wherein an orthographic projection of the first light-shielding portion on the base substrate is at least partially located at the first-direction side of an orthographic projection of the first sub-pixel on the base substrate, and the first light-shielding portion exposes at least part of the first sub-pixel;
wherein an orthographic projection of the first bottom light-shielding portion on the base substrate is at least partially located at the first-direction side of the orthographic projection of the first sub-pixel on the base substrate, and the first bottom light-shielding portion exposes at least part of the first sub-pixel;
wherein an orthographic projection of the second light-shielding portion on the base substrate is at least partially located at a second-direction side of an orthographic projection of the second sub-pixel on the base substrate, and the second light-shielding portion exposes at least part of the second sub-pixel, wherein the second-direction side is a side in a second direction;
wherein an orthographic projection of the second bottom light-shielding portion on the base substrate is at least partially located at a second-direction side of the orthographic projection of the second sub-pixel on the base substrate, and the second bottom light-shielding portion exposes at least part of the second sub-pixel, and the first direction is opposite to the second direction.

9. The display panel according to claim 8, wherein for two first light exit units which are adjacent along the first direction, a second light-shielding portion of a first light exit unit of the two first light exit units located at the first-direction side is reused as a first light-shielding portion of a first light exit unit two first light exit units located at the second-direction side, and a second bottom light-shielding portion of the first light exit unit located at the first-direction side is reused as a first bottom light-shielding portion of the first light exit unit located at the second-direction side.

10. The display panel according to claim 1, wherein the viewing-angle definition layer comprises a first black matrix layer, a light-transmitting medium layer, and a second black matrix layer which are sequentially stacked at a side of the pixel layer away from the base substrate, the viewing-angle definition layer has viewing-angle definition structures corresponding to the sub-pixel groups one to one, and the sub-pixel groups and corresponding viewing-angle definition structures form light exit units;
wherein the light exit units comprise a second light exit unit, and in the second light exit unit, the first sub-pixel is located at a third-direction side of the second sub-pixel, the viewing-angle definition structure of the second light exit unit comprises a first light-shielding portion and a first bottom light-shielding portion corresponding to the first sub-pixel, and a second light-shielding portion and a second bottom light-shielding portion corresponding to the second sub-pixel, wherein the third-direction side is a side in a third direction;
wherein the first bottom light-shielding portion and the second bottom light-shielding portion are located in the first black matrix layer, and the first light-shielding portion and the second light-shielding portion are located in the second black matrix layer;
wherein an orthographic projection of the first light-shielding portion on the base substrate is at least partially located at a first-direction side of an orthographic projection of the first sub-pixel on the base substrate, and the first light-shielding portion exposes at least part of the first sub-pixel, wherein the first-direction side is a side in a first direction;
wherein an orthographic projection of the first bottom light-shielding portion on the base substrate is at least partially located at the first-direction side of the orthographic projection of the first sub-pixel on the base substrate, and the first bottom light-shielding portion exposes at least a part of the first sub-pixel;
wherein an orthographic projection of the second light-shielding portion on the base substrate is at least partially located at a second-direction side of an orthographic projection of the second sub-pixel on the base substrate, and the second light-shielding portion exposes at least part of the second sub-pixel, wherein the second-direction side is a side in a second direction;
wherein an orthographic projection of the second bottom light-shielding portion on the base substrate is at least partially located at the second-direction side of the orthographic projection of the second sub-pixel on the base substrate, and the second bottom light-shielding portion exposes at least part of the second sub-pixel, and the first direction is opposite to the second direction and is perpendicular to the third direction.

11. (canceled)

12. The display panel according to claim 8, wherein in at least part of the light exit units, the first sub-pixel partially overlaps with the first bottom light-shielding portion, a size of a part of the first sub-pixel overlapping with the first bottom light-shielding portion in the first direction does not exceed half of a size of the first sub-pixel in the first direction;
wherein the first sub-pixel partially overlaps with the first light-shielding portion, and a size of a part of the first sub-pixel overlapping with the first light-shielding portion in the first direction does not exceed half of the size of the first sub-pixel in the first direction;
and/or, wherein in at least part of the light exit unit, the second sub-pixel partially overlaps with the second bottom light-shielding portion, and a size of a part of the second sub-pixel overlapping with the second bottom light-shielding portion in the first direction does not exceed half of a size of the second sub-pixel in the first direction;
wherein the second sub-pixel partially overlaps with the second light-shielding portion, and a size of a part of the second sub-pixel overlapping with the second light-shielding portion in the first direction does not exceed half of the size of the second sub-pixel in the first direction.

13. The display panel according to claim 1, wherein the viewing-angle definition layer comprises a first black matrix layer, a light-transmitting medium layer and a second color filter layer which are sequentially stacked at a side of the pixel layer away from the base substrate, the viewing-angle definition layer comprises viewing-angle definition structures corresponding to the sub-pixel groups one to one, and the sub-pixel groups and corresponding viewing-angle definition structures constitute light exit units;
wherein the light exit units comprises at least one first light exit unit, and in the first light exit unit, the first sub-pixel is located at a first-direction side of the second sub-pixel, the viewing-angle definition structure of the first light exit unit comprises a first color resist unit corresponding to the first sub-pixel, a second color resist unit corresponding to the second sub-pixel, an auxiliary color resist unit between the first color resist unit and the second color resist unit, and a bottom light-shielding portion located in the first black matrix layer, wherein the first-direction side is a side in a first direction;
wherein the first color resist unit, the second color resist unit and the auxiliary color resist unit are located in the second color filter layer, colors of the first color resist unit and the second color resist unit are the same as a light-emitting color of a sub-pixel group of the first light exit unit, and a color of the auxiliary color resist unit is different from the light-emitting color of the sub-pixel group of the first light exit unit;
wherein an orthographic projection of the first color resist unit on the base substrate is located at the first-direction side of an orthographic projection of the first sub-pixel on the base substrate, and an orthographic projection of the second color resist unit on the base substrate is located at a second-direction side of an orthographic projection of the second sub-pixel on the base substrate, wherein the second-direction side is a side in a second direction,
wherein an orthographic projection of the bottom light-shielding portion on the base substrate at least covers an orthographic projection of a gap between the first sub-pixel and the second sub-pixel on the base substrate;
wherein a light path between the second sub-pixel and the first color resist unit is blocked by the bottom light-shielding portion, and a light path between the first sub-pixel and the second color resist unit is blocked by the bottom light-shielding portion;
wherein the first direction is opposite to the second direction.

14. The display panel according to claim 13, wherein in at least part of the at least one first light exit units, the bottom light-shielding portion partially overlaps with the first sub-pixel, and a size of a part of the first sub-pixel overlapping with the bottom light-shielding portion in the first direction does not exceed half of a size of the first sub-pixel in the first direction;
and/or, wherein in at least part of the first light exit unit, the second sub-pixel partially overlaps with the bottom light-shielding portion, and a size of a part of the second sub-pixel overlapping with the bottom light-shielding portion in the first direction does not exceed half of a size of the second sub-pixel in the first direction.

15. The display panel according to claim 13, wherein the auxiliary color resist unit comprises a first auxiliary color resist unit and a second auxiliary color resist unit, and the first auxiliary color resist unit is located at a first-direction side of the second auxiliary color resist unit;
wherein for two first light exit units which are adjacent along the first direction, a second auxiliary color resist unit of a first light exit unit of the two first light exit units located at the first-direction side is reused as a first color resist unit of a first light exit unit of the two first light exit units located at the second-direction side, and a first auxiliary color resist unit of the first light exit unit located at the second-direction side is reused as a second color resist unit of the first light exit unit located at the first-direction side.

16. The display panel according to claim 13, wherein in at least part of the at least one first light exit units, the auxiliary color resist unit comprises a first auxiliary color resist unit and a second auxiliary color resist unit, and the first auxiliary color resist unit is located at a first-direction side of the second auxiliary color resist unit;
wherein an orthographic projection of the first auxiliary color resist unit on the base substrate covers the orthographic projection of the first sub-pixel on the base substrate, and an orthographic projection of the second auxiliary color resist unit on the base substrate covers the orthographic projection of the second sub-pixel on the base substrate;
or, wherein in at least part of the at least one first light exit units, the auxiliary color resist unit comprises a first auxiliary color resist unit and a second auxiliary color resist unit, and the first auxiliary color resist unit is located at a first-direction side of the second auxiliary color resist unit, and the first light exit unit further comprises a light-shielding portion between the first auxiliary color resist unit and the second auxiliary color resist unit and arranged in the second color filter layer.

17. (canceled)

18. The display panel according to claim 1, wherein the viewing-angle definition layer comprises a first black matrix layer, a light-transmitting medium layer, and a second color filter layer which are sequentially stacked at a side of the pixel layer away from the base substrate, the viewing-angle definition layer comprises viewing-angle definition structures corresponding to the sub-pixel groups one to one, and the sub-pixel groups and corresponding viewing-angle definition structures constitute light exit units;
wherein the light exit units comprises a second light exit unit, and in the second light exit unit, the first sub-pixel is located at a third-direction side of the second sub-pixel, the viewing-angle definition structure of the second light exit unit comprises a first color resist unit and a first bottom light-shielding portion corresponding to the first sub-pixel, a second color resist unit and a second bottom light-shielding portion corresponding to the second sub-pixel, and an auxiliary color resist unit between the first color resist unit and the second color resist unit, wherein the third-direction side is a side in a third direction;
wherein the first color resist unit, the second color resist unit and the auxiliary color resist unit are located in the second color filter layer, and colors of the first color resist unit and the second color resist unit are the same as a light-emitting color of a sub-pixel group of the second light exit unit, and a color of the auxiliary color resist unit is different from the light-emitting color of the sub-pixel group of the second light exit unit;
wherein the first bottom light-shielding portion and the second bottom light-shielding portion are located in the first black matrix layer;
wherein an orthographic projection of the first color resist unit on the base substrate is located at a first-direction side of an orthographic projection of the first sub-pixel on the base substrate, and the first-direction side is a side in the first direction;
wherein an orthographic projection of the second color resist unit on the base substrate is located at a second-direction side of an orthographic projection of the second sub-pixel on the base substrate, and the second-direction side is a side in the second direction;
wherein an orthographic projection of the first bottom light-shielding portion on the base substrate is at least partially located at the second-direction side of the orthographic projection of the first sub-pixel on the base substrate;
wherein an orthographic projection of the second bottom light-shielding portion on the base substrate is at least partially located at the first-direction side of the orthographic projection of the second sub-pixel on the base substrate;
wherein a light path between the second sub-pixel and the first color resist unit is blocked by the second bottom light-shielding portion, and a light path between the first sub-pixel and the second color resist unit is blocked by the first bottom light-shielding portion;
wherein the first direction is opposite to the second direction and is perpendicular to the third direction.

19. (canceled)

20. The display panel according to claim 1, wherein the driving layer has pixel driving circuit groups corresponding to the sub-pixel groups one to one, and one of the pixel driving circuit groups comprises a first pixel driving circuit for driving a first sub-pixel in a corresponding sub-pixel group and a second pixel driving circuit for driving a second sub-pixel in the corresponding sub-pixel group;
wherein the first pixel driving circuit and the second pixel driving circuit share a part of transistors.

21. The display panel according to claim 20, wherein the one of the pixel driving circuit groups comprises:
a pixel driving module configured to provide a driving current;
a first light-emitting control module configured to, in response to a first light-emitting control signal, cause the driving current to flow to the first sub-pixel; and
a second light-emitting control module configured to, in response to a second light-emitting control signal, cause the driving current flow to the second sub-pixel.

22. The display panel according to claim 21, wherein the one of the pixel driving circuit groups further comprises:
a first reset module configured to reset a voltage on a pixel electrode of the first sub-pixel in response to a first electrode reset signal; and
a second reset module configured to reset a voltage on a pixel electrode of the second sub-pixel in response to a second electrode reset signal;
or, wherein one of the first light-emitting control module and the second light-emitting control module is an N-type transistor, and the other one of the first light-emitting control module and the second light-emitting control module is a P-type transistor, and a gate of the N-type transistor and a gate of the P-type transistor are connected to a same light-emitting control signal line.

23-24. (canceled)

25. A display device comprising display panel;
wherein the display panel comprises a base substrate, a driving layer, a pixel layer and a viewing-angle definition layer stacked sequentially, wherein the pixel layer comprises sub-pixel groups arranged in an array, and any one of the sub-pixel groups comprises a first sub-pixel and a second sub-pixel which are adjacent and have a same color;
wherein the viewing-angle definition layer is capable of making a light exit projection space of the first sub-pixel at most partially overlap with a light exit projection space of the second sub-pixel.

26. A driving method for driving a display device, applied to a display device comprising a display panel,
wherein the display panel comprises a base substrate, a driving layer, a pixel layer and a viewing-angle definition layer stacked sequentially, wherein the pixel layer comprises sub-pixel groups arranged in an array, and any one of the sub-pixel groups comprises a first sub-pixel and a second sub-pixel which are adjacent and have a same color;
wherein the viewing-angle definition layer is capable of making a light exit projection space of the first sub-pixel at most partially overlap with a light exit projection space of the second sub-pixel;
wherein the driving method for driving the display device comprises:
at a first moment, enabling each of first sub-pixels to emit light to display a first image; and
at a second moment, enabling each of second sub-pixels to emit light to display a second image.

27. The driving method for driving the display device according to claim 26, wherein the driving method further comprises:
in response to a switching instruction, performing switching between a privacy mode and a non-privacy mode, wherein the first image and the second image are different in the privacy mode, and the first image and the second image are the same in the non-privacy mode.
